(19) United States
(12) Patent Application Publication
(10) Pub. No.: US 2013/0107491 A1
(43) Pub. Date: May 2, 2013

(54) ELECTRONIC APPARATUS

(71) Applicants: Masaharu Imazato, Tokyo (JP); Hiroshi Toyao, Tokyo (JP); Naoki Kobayashi, Tokyo (JP); Noriaki Ando, Tokyo (JP)

(72) Inventors: Masaharu Imazato, Tokyo (JP); Hiroshi Toyao, Tokyo (JP); Naoki Kobayashi, Tokyo (JP); Noriaki Ando, Tokyo (JP)

(21) Appl. No.: 13/809,875

(22) PCT Filed: Jul. 6, 2011
(86) PCT No.: PCT/JP2011/003869

§ 371 Date: Jan. 11, 2013

(30) Foreign Application Priority Data
Jul. 12, 2010 (JP) 2010-158205

(51) Int. Cl. H05K 9/00

(52) U.S. Cl. CPC H05K 9/0009
USPC 361/809

(57) ABSTRACT

Provided is means for suppressing noise from leaking to the outside of a frame via a gap in an electronic apparatus in which an electronic component is included in a frame which has conductive properties and has a gap that connects an inner space and an external space. An electronic apparatus includes: a conductive frame (10) having a gap (40) that connects an inner space and an external space; an electronic component (20) stored in the frame (10); and a structure (30) provided in contact with an inner wall surface (11) of the frame (10), wherein the structure (30) includes a conductive material layer, and a dielectric material layer positioned between the conductive material layer and the inner wall surface (11) of the frame (10), and the conductive material layer includes a repeated structure in at least a partial area thereof.

### TECHNICAL FIELD

The present invention relates to an electronic apparatus.

### BACKGROUND ART

Electronic apparatuses in which electronic components are included in a conductive frame are known. Among these electronic apparatuses, an electronic apparatus in which a gap that connects an inner space and an external space of the frame is present in the frame is known. For example, a PC (Personal Computer) is an example thereof.

PCs include electronic components such as an electronic circuit board which are provided in a frame that is formed of an Mg alloy, for example. In the case of notebook-type PCs, for example, a cover for installing more-memory is provided on a bottom surface thereof, and a gap that connects an inner space and an external space of the frame is present between the cover and the frame body. Examples of such an electronic apparatus in which a gap that connects the inner space and the external space of the frame include, as well as PCs, various types of electronic apparatuses such as a projector.

Here, in the case of the electronic apparatus having the above-described configuration, a problem in which noise generated as a result of the operation of the electronic component provided in the frame propagates through the inner wall surface of the frame and leaks into an external space via the gap present in the frame may occur.

Patent Document 1 discloses means for suppressing the leakage of noise via the gap using a structure in which a shielding member is provided in the gap included in the frame to cover the gap that connects the inner space of the frame and the external space as means for solving the problem.

### RELATED DOCUMENT

### Patent Document

[Patent Document 1] Japanese Unexamined patent publication No. 2001-77576

### DISCLOSURE OF THE INVENTION

However, like the technique disclosed in Patent Document 1, in the case of the means for suppressing the leakage of noise by performing direct processing (for example, covering the gap with the shielding member) on the gap present in the frame, the following problem occurs.

For example, as described above, when the gap present between the cover provided on the bottom surface of the notebook-type PC so as to install more memory and the frame body is covered with the shielding member, although the cover may be opened and closed in order to install more memory, the state of the gap covered with the shielding member may change. Thus, there is a concern that a sufficient noise leakage suppression effect is not obtained after the covered state is changed.

Moreover, when a gap is formed intentionally to provide a certain function, a problem may occur if the gap is covered with a shielding member.

Therefore, an object of the present invention is to provide means for suppressing a problem such as leakage of noise to the outside of the frame via the gap without performing any direct processing on the gap present in the frame.

According to the present invention, there is provided an electronic apparatus including: a frame which has conductive properties and has a gap that connects an inner space and an external space; an electronic component stored in the frame; and a structure provided in contact with an inner wall surface of the frame, wherein the structure includes a conductive material layer, and a dielectric material layer positioned between the conductive material layer and the inner wall surface of the frame, and the conductive material layer includes a repeated structure in at least a partial area thereof.

According to the present invention, it is possible to suppress the occurrence of a problem of leakage of noise from an inner space of an electronic apparatus to an external space.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view schematically illustrating an example of an electronic apparatus according to the present embodiment;

FIG. 2 is a bottom view schematically illustrating an example of an electronic apparatus according to the present embodiment;

FIG. 3 is a cross-sectional view schematically illustrating an example of an electronic apparatus according to the present embodiment;

FIG. 4 is a side view schematically illustrating an example of an electronic apparatus according to the present embodiment;

FIG. 5 is a cross-sectional view schematically illustrating an example of an inner wall surface and a structure of a frame according to the present embodiment;

FIG. 6 is a perspective view schematically illustrating an example of an EBG structure provided in an electronic apparatus according to the present embodiment;

FIG. 7 is a cross-sectional view schematically illustrating an example of an EBG structure provided in an electronic apparatus according to the present embodiment;

FIG. 8 is an equivalent circuit diagram of a unit cell of an EBG structure provided in an electronic apparatus according to the present embodiment;

FIG. 9 is an equivalent circuit diagram of an EBG structure provided in an electronic apparatus according to the present embodiment;

FIG. 10 is a formula that calculates a frequency range of noise of which the propagation is suppressed by an EBG structure;

FIG. 11 is a cross-sectional view for explaining a position at which a structure according to the present embodiment is provided;

FIG. 12 is a cross-sectional view for explaining an example of a method of manufacturing a structure according to the present embodiment;

FIG. 13 is a cross-sectional view schematically illustrating an example of an inner wall surface and a structure of a frame according to the present embodiment;

FIG. 14 is a cross-sectional view schematically illustrating an example of an inner wall surface and a structure of a frame according to the present embodiment;

FIG. 15 is a plan view schematically illustrating an example of a structure according to the present embodiment;

FIG. 16 is an equivalent circuit diagram of a unit cell of an EBG structure provided in an electronic apparatus according to the present embodiment;

FIG. 17 is a cross-sectional view for explaining an example of a method of manufacturing a structure according to the present embodiment;

FIG. 18 is a cross-sectional view schematically illustrating an example of an inner wall surface and a structure of a frame according to the present embodiment;

FIG. 19 is a cross-sectional view schematically illustrating an example of an inner wall surface and a structure of a frame according to the present embodiment;

FIG. 20 is a plan view schematically illustrating an example of a structure according to the present embodiment;

FIG. 21 is an equivalent circuit diagram of a unit cell of an EBG structure provided in an electronic apparatus according to the present embodiment;

FIG. 22 is a cross-sectional view schematically illustrating an example of an inner wall surface and a structure of a frame according to the present embodiment;

FIG. 23 is a cross-sectional view for explaining an example of a method of manufacturing a structure according to the present embodiment;

FIG. 24 is a cross-sectional view schematically illustrating an example of an inner wall surface and a structure of a frame according to the present embodiment;

FIG. 25 is a perspective view schematically illustrating an example of an island-shaped conductor according to the present embodiment;

FIG. 26 is a perspective view schematically illustrating an example of an EBG structure provided in an electronic apparatus according to the present embodiment;

FIG. 27 is a cross-sectional view schematically illustrating an example of an EBG structure provided in an electronic apparatus according to the present embodiment;

FIG. 28 is an equivalent circuit diagram of a unit cell of an EBG structure provided in an electronic apparatus according to the present embodiment;

FIG. 29 is a perspective view schematically illustrating an example of an island-shaped conductor according to the present embodiment;

FIG. 30 is a perspective view schematically illustrating an example of an EBG structure provided in an electronic apparatus according to the present embodiment;

FIG. 31 is an equivalent circuit diagram of a unit cell of an EBG structure provided in an electronic apparatus according to the present embodiment;

FIG. 32 is a cross-sectional view schematically illustrating an example of an inner wall surface and a structure of a frame according to the present embodiment;

FIG. 33 is a cross-sectional view schematically illustrating an example of an inner wall surface and a structure of a frame according to the present embodiment;

FIG. 34 is a cross-sectional view schematically illustrating an example of an inner wall surface and a structure of a frame according to the present embodiment;

FIG. 35 is a cross-sectional view schematically illustrating an example of an inner wall surface and a structure of a frame according to the present embodiment;

FIG. 36 is a plan view schematically illustrating an example of a third conductor according to the present embodiment;

FIG. 37 is a plan view schematically illustrating an example of a third conductor according to the present embodiment;

FIG. 38 is a perspective view schematically illustrating an example of an EBG structure provided in an electronic apparatus according to the present embodiment;

FIG. 39 is a perspective view schematically illustrating an example of an EBG structure provided in an electronic apparatus according to the present embodiment;

FIG. 40 is a diagram schematically illustrating a cross-sectional structure according to a comparative example;

FIG. 41 is a diagram illustrating a structure according to a comparative example;

FIG. 42 is a diagram illustrating a structure according to an example; and

FIG. 43 is a diagram illustrating electromagnetic field simulation results.

### DESCRIPTION OF EMBODIMENTS

Hereinafter, embodiments of the present invention will be described with reference to drawings. Throughout the drawings, the same constituent components will be denoted by the same reference numerals, and description thereof will not be provided appropriately.

### First Embodiment

First, an overall configuration of an electronic apparatus according to the present embodiment will be described.

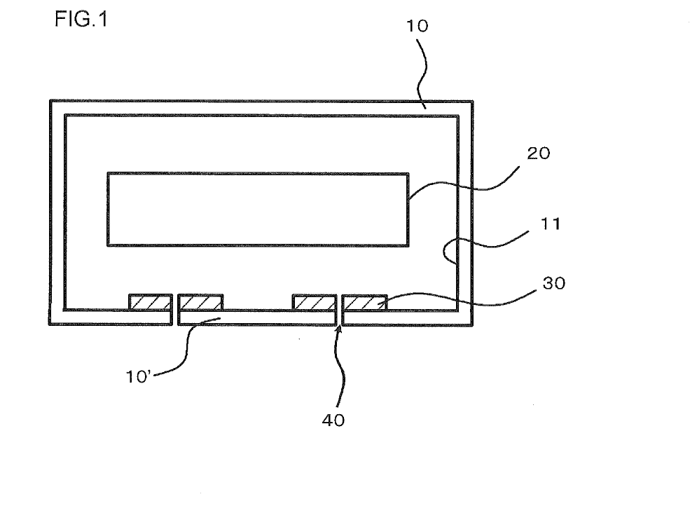

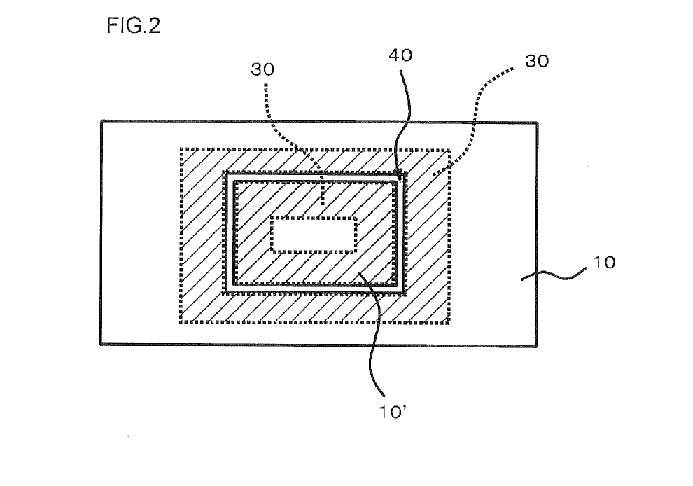

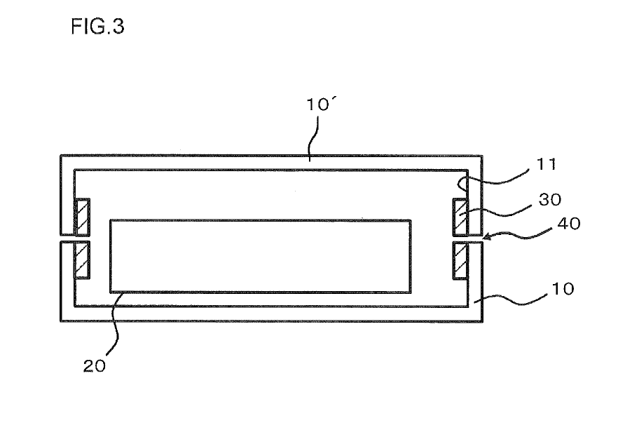

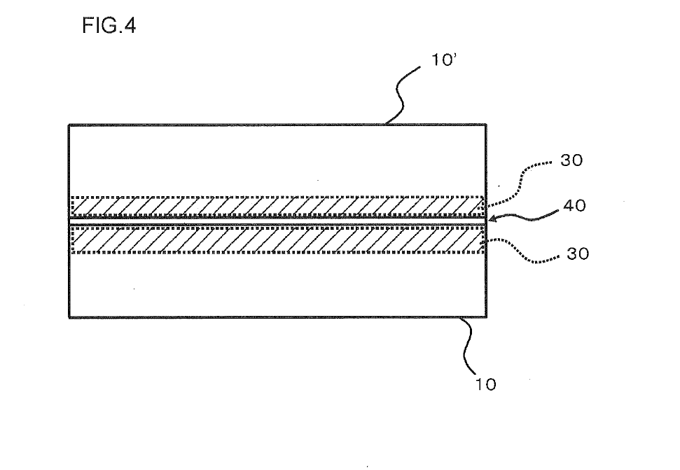

FIG. 1 is a cross-sectional view schematically illustrating an example of an electronic apparatus according to the present embodiment, and FIG. 2 is a bottom view of the electronic apparatus of FIG. 1. Moreover, FIG. 3 is a cross-sectional view schematically illustrating another example of an electronic apparatus according to the present embodiment, and FIG. 4 is a side view of the electronic apparatus of FIG. 3.

As illustrated in FIGS. 1 to 4, the electronic apparatus according to the present embodiment includes a frame 10, an electronic component 20, and a structure 30.

Here, the electronic apparatus having the configuration illustrated in FIGS. 1 and 2 is a notebook-type PC, for example. In the drawings, reference numeral 10′ designates a portion of the frame 10 and corresponds to a cover for installing more memory, for example. A user may perform an operation of opening the cover 10′, setting memory at a predetermined position, and closing the cover 10′ as necessary. A gap 40 that connects an inner space of the frame 10 and an external space is present between the cover 10′ and the body of the frame 10. A projector is an example of the electronic apparatus having the configuration illustrated in FIGS. 3 and 4. In the drawings, reference numeral 10′ is a portion of the frame 10 and corresponds to a cover that is fitted to the frame 10 (body), for example. The gap 40 that connects the inner space and the external space of the frame 10 is present between the cover 10′ and the body of the frame 10. The PC and the projector are examples only, and the electronic apparatus according to the present embodiment may be other types of electronic apparatuses. Moreover, the structures illustrated in FIGS. 1 to 4 are examples only and are not limited to such a configuration.

Hereinafter, the respective configurations of the electronic apparatus according to the present embodiment will be described.

The frame 10 has conductive properties in at least a partial area of the inner wall surface. That is, at least a partial area of the inner wall surface of the frame 10 is configured to include a conductive material. The conductive material is not particularly limited. Moreover, the position, shape, and size of the conductive area in the inner wall surface of the frame 10 are not particularly limited.

The frame 10 includes the gap 40 that connects the inner space and the external space. The gap 40 is present in the conductive area of the frame 10. When the frame 10 includes an area that does not have conductive properties, the gap 40 may be present over the conductive area and the non-conductive area. The gap 40 maybe one which is provided intentionally for a certain purpose when designing an electronic apparatus and may be one which is necessarily present when designing an electronic apparatus (in particular, the frame 10). The shape and size of such a gap 40 is not particularly limited, and the gap 40 may have an optional shape. For example, a gap having a dot shape in a plan view and a gap having a line shape (including a straight line and a curve) in a plan view maybe used. Moreover, the gap 40 may be present in one surface of the frame 10 as illustrated in FIGS. 1 and 2, and the gap 40 may be present over a plurality of surfaces of the frame 10 as illustrated in FIGS. 3 and 4. In the examples described with reference to FIGS. 1 to 4, although the gap 40 formed between the frame 10 and the cover 10′ that is a portion of the frame 10 is illustrated, this is an example only, and the gap 40 of the present embodiment is not limited to such a gap.

In addition to the above, the shape, size, aspect ratio, and the like of the frame 10 illustrated in FIGS. 1 to 4 are examples only, and in the present embodiment, are not limited to these examples.

The electronic component 20 is stored in the frame 10. The type of the electronic component 20 is not particularly limited, and an electronic circuit board is an example of the electronic component 20.

Here, when the electronic component 20 is stored in the frame 10 having the above configuration, induced noise current may flow in the conductive inner wall surface of the frame 10 near the electronic component 20 due to a magnetic field caused by operating signal current flowing in the electronic component 20. There is a concern that the induced noise current moves through the conductive inner wall surface of the frame 10 to reach the gap 40, then moves to the external space of the frame 10 via the gap 40, and radiates in the air as electromagnetic waves, for example.

In the electronic apparatus according to the present embodiment, the structure 30 having a function of eliminating the problems described above is provided in contact with the conductive inner wall surface of the frame 10. The structure 30 includes a dielectric material layer and a conductive material layer that has a repeated structure in at least a partial area. Hereinafter, the structure 30 will be described in detail.

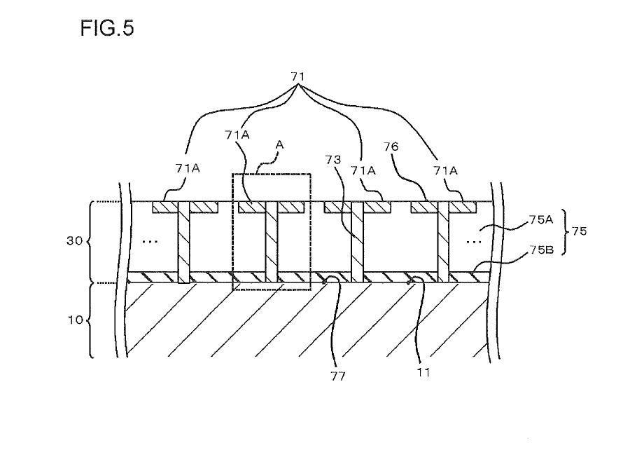

FIG. 5 schematically shows an example of a cross-sectional structure of the structure 30 that is provided in contact with the conductive inner wall surface 11 (hereinafter simply referred to as an “inner wall surface 11”) of the frame 10.

As illustrated in FIG. 5, the structure 30 includes first conductors 71, connection members 73, and a dielectric material layer 75.

The dielectric material layer 75 is provided in contact with the inner wall surface 11. Moreover, the dielectric material layer 75 is configured such that at least a portion thereof forms an adhesion layer 75B that is attached to the inner wall surface 11. For example, as illustrated in FIG. 5, the dielectric material layer 75 may be a stacked structure that includes a layer 75A formed of a dielectric material and an adhesion layer 75B. The layer 75A may be a flexible substrate, for example. Further, specifically, the layer 75A may be a glass epoxy substrate, a fluorine resin substrate, or the like, for example. The layer 75A may be made up of a single layer or a plurality of layers. The adhesion layer 75B may be formed of an adhesive, for example. A raw material of the adhesive is not particularly limited, and all raw materials according to the related art such as natural rubber, an acrylic resin, or silicone may be used, for example. The thicknesses of the layer 75A and the adhesion layer 75B are design matters.

The first conductors 71 are provided on a surface of the dielectric material layer 75, specifically on a surface 76 on a side opposite to a surface 77 of the dielectric material layer 75 that is in contact with the inner wall surface 11 so as to face the inner wall surface 11. The first conductors 71 may be provided in an inner portion of the dielectric material layer 75 so as to face the inner wall surface 11. Such first conductors 71 have a repeated structure (for example, a periodic structure) in at least a partial area. As the repeated structure, as illustrated in FIG. 5, a structure in which a plurality of separated island-shaped conductors 71A are repeatedly (for example, periodically) provided may be considered.

The expression “repeated” of the island-shaped conductors 71A also includes a case where the island-shaped conductors 71A are partially omitted. Moreover, the expression “periodic” also includes a case where an arrangement of partial island-shaped conductors 71A themselves is offset. That is, even when periodicity collapses in the strict sense of meaning, if the island-shaped conductors 71A are disposed repeatedly, since it is possible to obtain the metamaterial properties of an EBG structure (described later) in which the island-shaped conductors 71A are part of constituent components thereof, a certain degree of defects is allowed in “periodicity.”

A raw material of the island-shaped conductor 71A is not particularly limited, and copper or the like may be selected, for example. The plan-view shape of the island-shaped conductor 71A is not particularly limited, and an optional shape such as a triangle, a quadrangle, a pentagon, a polygon having six apexes or more, or a circle may be used. Two or more types of island-shaped conductors 71A having different sizes and/or shapes may be disposed repeatedly. In such a case, it is preferable that two or more types of island-shaped conductors 71A be periodically arranged for each type. The size, mutual-distance, and the like of the island-shaped conductors 71A are determined according to a desired bandgap range set to the EBG structure (described later) in which the island-shaped conductors 71A are part of constituent components thereof.

The connection members 73 are provided in an inner portion of the dielectric material layer 75 so as to electrically connect part or all of the island-shaped conductors 71A and the inner wall surface 11. That is, the connection members 73 are exposed at least on a side of the surface 77 (the surface in contact with the inner wall surface 11) of the dielectric material layer 75 and are in contact with the inner wall surface 11 and part or all of the island-shaped conductors 71A. When the connection members 73 are provided so as to electrically connect part of the island-shaped conductors 71A and the inner wall surface 11, the connection members 73 may be provided periodically and may not be provided periodically. However, it is preferable that the connection members 73 are provided periodically since an EBG structure (described later) in which the connection members 73 are part of constituent components thereof causes Bragg reflection to extend the bandgap range. Here, the expression “periodic” includes a case where an arrangement of partial connection members 73 themselves is offset. Such connection members 73 may be formed of metal such as copper, aluminum, or stainless steel, for example.

The structure 30 according to the present embodiment is a sheet that includes the adhesion layer 75B, and a state illustrated in FIG. 5 is obtained by attaching the sheet-like structure 30 to the inner wall surface 11 of the frame 10.

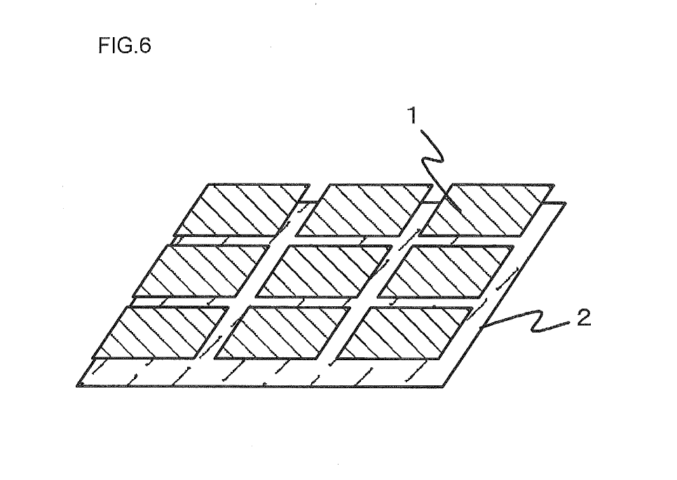

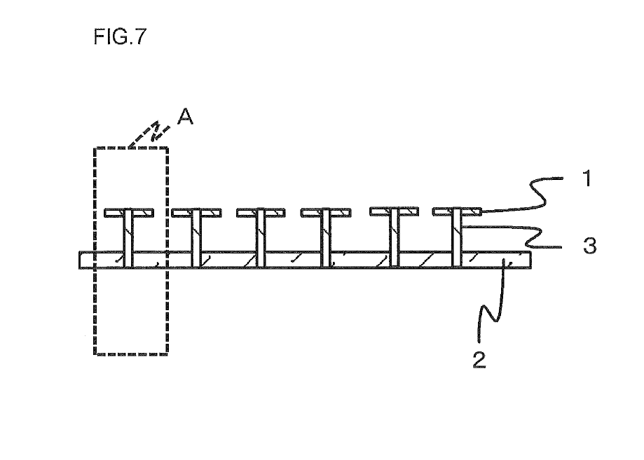

Here, in the present embodiment, the inner wall surface 11 and the structure 30 form an EBG structure. FIGS. 6 and 7 schematically illustrate an example of an EBG structure that includes the inner wall surface 11 and the structure 30. FIG. 6 is a perspective view schematically illustrating a configuration of the EBG structure, and FIG. 7 is a cross-sectional view of the EBG structure of FIG. 6.

The EBG structure illustrated in FIGS. 6 and 7 includes a sheet-like conductor 2, a plurality of separated island-shaped conductors 1, and a plurality of connection members 3. The sheet-like conductor 2 corresponds to the inner wall surface 11, the island-shaped conductors 1 correspond to the island-shaped conductors 71A of the structure 30, and the connection members 3 correspond to the connection members 73 of the structure 30.

The plurality of island-shaped conductors 1 are disposed in areas that overlap the sheet-like conductor 2 in plan view and are disposed at a position separated from the sheet-like conductor 2 with a dielectric material layer (not illustrated) interposed. Moreover, the plurality of island-shaped conductors 1 is arranged periodically. The connection members 3 electrically connect each of the plurality of island-shaped conductors 1 to the sheet-like conductor 2. In the EBG structure, a unit cell A includes one island-shaped conductor 1, the connection member 3 provided so as to correspond to the island-shaped conductor 1, and a partial area of the sheet-like conductor 2 including an area that faces the island-shaped conductor 1. The unit cells A are disposed repeatedly (for example, periodically), whereby the structure functions as a metamaterial (for example, an EBG (Electromagnetic Band Gap)). The EBG structure is an EBG structure having a so-called mushroom structure.

Here, the expression “repeated” of the unit cells A includes a case where part of the configurations of some unit cells A is omitted. Moreover, when the unit cells A have a two-dimensional arrangement, the expression “repeated” also includes a case where the unit cells A are partially omitted. Moreover, the expression “periodic” includes a case where part of the constituent components (the island-shaped conductor 1 and the connection member 3) of partial unit cells A is offset and a case where an arrangement of partial unit cells A themselves is offset. That is, even when periodicity collapses in the strict sense of meaning, if the unit cells A are disposed repeatedly, since it is possible to obtain the metamaterial properties, a certain degree of defects is allowed in “periodicity.” As the cause of the occurrence of these defects, a case where an interconnect or a via passes between the unit cells A, a case where it is not possible to dispose a unit cell A due to an existing via or pattern when adding a metamaterial structure to an existing interconnect layout, a manufacturing error, and a case where an existing via or pattern is used as a portion of a unit cell can be considered. The above assumption is true for all of the following embodiments.

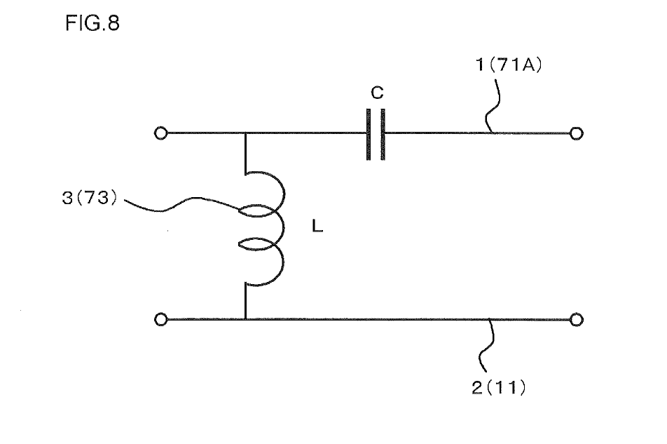

FIG. 8 is an equivalent circuit diagram of the unit cell A illustrated in FIG. 7. As illustrated in FIG. 8, the unit cell A includes a capacitance C generated between the neighboring island-shaped conductors 1 and an inductance L created by the connection member 3.

According to the EBG structure, it is possible to suppress propagation of noise current on the surface of the sheet-like conductor 2. Moreover, since the neighboring island-shaped conductors 1 form a capacitance C, it is possible to suppress propagation of noise electromagnetic waves near the EBG structure.

Here, in the EBG structure, a frequency range serving as a bandgap can be adjusted by adjusting the distance between the island-shaped conductor 1 and the sheet-like conductor 2, the thickness of the connection member 3, the mutual distance between the plurality of island-shaped conductors 1, and the like. That is, the EBG structure can adjust the frequency of noise of which the propagation is suppressed.

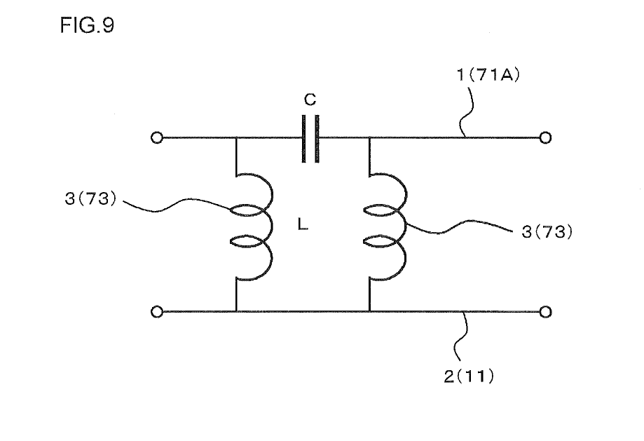

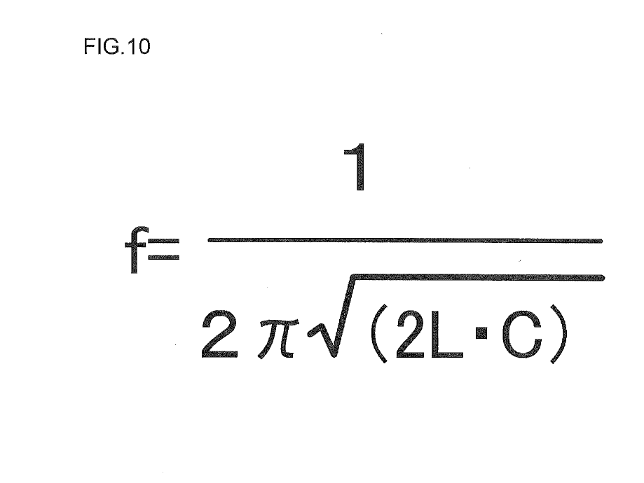

For example, in the case of the EBG structure illustrated in FIG. 7, two neighboring island-shaped conductors 1, two connection members 3 connected to the respective two island-shaped conductors 1, and a partial area including an area of the sheet-like conductor 2 facing the two island-shaped conductors 1 can be depicted by an equivalent circuit diagram illustrated in FIG. 9. A bandgap range “f” of the EBG structure depicted by such an equivalent circuit diagram can be calculated by a formula illustrated in FIG. 10. By appropriately adjusting the capacitance C and/or the inductance L that form the EBG structure according to this formula, it is possible to set a desired f-value.

Further, specifically, for example, by changing the distance between the neighboring island-shaped conductors 1, the size of the island-shaped conductors 1, and the length of the connection member 3, it is possible to appropriately adjust the capacitance C and/or the inductance L and to set a desired f-value. In the case of EBG structures having other configurations described in the following embodiments, by appropriately adjusting the capacitance C and/or the inductance L based on the formula for calculating the bandgap range “f” determined by each of the EBG structures, it is possible to set a desired f-value.

In the present embodiment, the inner wall surface 11 and the structure 30 form two types of EBG structures or more of which the bandgap ranges are different, and each of these EBG structures may be disposed repeatedly (for example, periodically). By doing so, it is possible to broaden the bandgap range.

In the electronic apparatus according to the present embodiment, the inner wall surface 11 and the structure 30 form the EBG structure described above. Thus, it is possible to suppress propagation of noise current in an area of the inner wall surface 11 where the structure 30 is provided and to suppress propagation of noise electromagnetic waves near the structure 30. In addition, by appropriately designing the island-shaped conductor 71A, the connection member 73, and the dielectric material layer 75 that constitute the structure 30, it is possible to appropriately suppress propagation of noise of a desired frequency.

Subsequently, assuming the operational effects obtained as a result of providing the structure 30, a preferred position at which the structure 30 is provided will be described.

As described above, at the position where the structure 30 is provided, it is possible to suppress propagation of noise current via the inner wall surface 11. Taking this into consideration, it is preferable to provide the structure 30 at a position such that the noise current propagating through the inner wail surface 11 is inhibited from reaching the gap 40. For example, as illustrated in FIGS. 1 to 4, the structure 30 may be provided so as to surround the gap 40. The structure 30 may be provided on the entire surface of the inner wall surface 11. Here, the expression “entire surface” means an entire surface at positions where the sheet-like structure 30 according to the present embodiment can be attached.

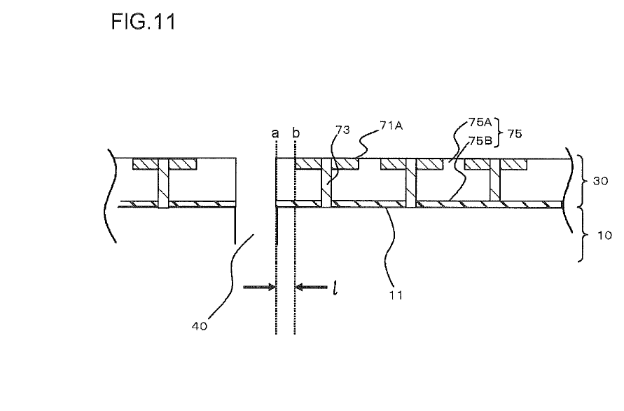

If the distance between the gap 40 and the structure 30 is so large, there is a concern that induced noise current flows in the inner wall surface 11 present therebetween and reaches the gap 40. Thus, it is preferable to provide the structure 30 at a position where the problem can be avoided. Hereinafter, this position will be described with reference to FIG. 11.

Focusing on the propagation of the noise current via the inner wall surface 11, it can be considered that an end portion a of the gap 40 is an open end, and a right side in the figure further than an end portion b of the island-shaped conductor 71A is in a shorted state due to the suppression function of the EBG structure. At a frequency where a maximum voltage appears at the end portion a which is an open end and a minimum voltage appears at the end portion b which is a shorted end, a ¼-wavelength resonance state is established, and there is a concern that noise moves to the external space via the gap 40. Therefore, when a distance in a direction parallel to the inner wall surface 11 from the gap 40 present in the inner wall surface 11 of the frame 10 to the island-shaped conductor 71A (the conductive material layer) of the structure 30 provided in contact with the inner wall surface 11 is 1 (mm), and an operating frequency of the electronic component 20 is f (GHz), it is preferable to satisfy a relation of 1≦(300/f)/4. It is more preferable to satisfy a relation of 1≦(300/f)/8. By doing so, it is possible to suppress the above problem.

According to the electronic apparatus according to the present embodiment having the configuration described above, it is possible to suppress the noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

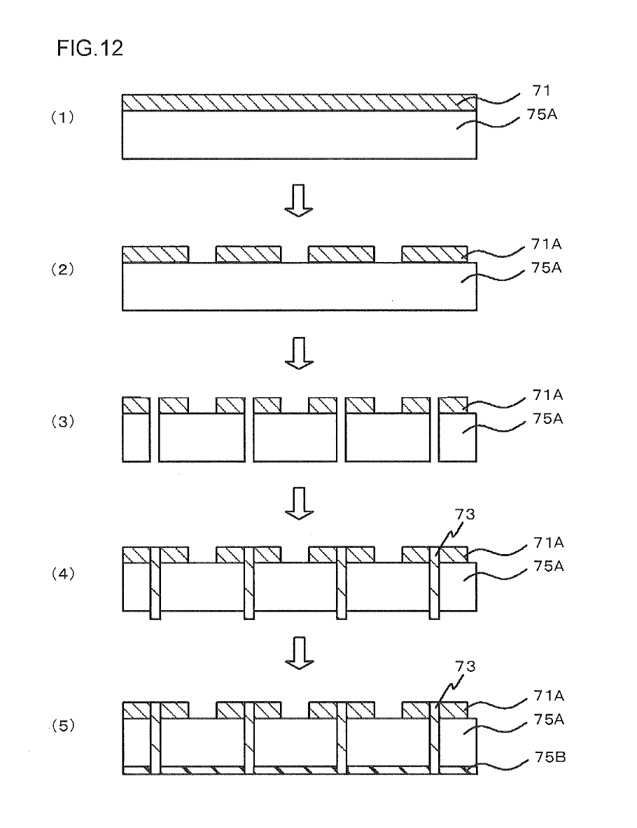

Next, an example of a method of manufacturing the structure 30 according to the present embodiment will be described with reference to FIG. 12. FIG. 12 is a cross-sectional view illustrating an example of the steps of manufacturing the structure 30 according to the present embodiment.

First, as illustrated in (1), a copper foil 71 is formed on a first surface (an upper surface in the figure) of a substrate (the layer 75A) such as a glass epoxy substrate or a fluorine resin substrate. Subsequently, as illustrated in (2), a portion of the copper foil 71 is selectively etched by photolithography and etching to form a pattern (the plurality of separated island-shaped conductors 71A). After that, as illustrated in (3), holes that penetrate through the island-shaped conductors 71A and the layer 75A are formed by drilling.

Subsequently, as illustrated in (4), penetration pins (the connection members 73) formed of metal such as copper, aluminum, or stainless steel are inserted into the holes formed in (3).

After that, as illustrated in (5), the adhesion layer 75B is formed on a second surface (the lower surface in the figure) of the layer 75A. The adhesion layer 75B is formed so that the connection members 73 penetrate through the adhesion layer 75B and are exposed. Specific means for forming in this manner is not particularly limited, but the following means may be used. For example, the length of the connection members 73 inserted in (4) is set to a length such that one set of ends of the connection members 73 in the inserted state are exposed from the second surface (the lower surface in the figure) of the layer 75A. Moreover, the adhesion layer 75B may be formed of a sheet-like adhesive, and when the sheet-like adhesive (the adhesion layer 75B) is formed on the second surface of the layer 75A, by strongly pressing the sheet-like adhesive (the adhesion layer 75B), one set of ends of the connection members 73 may be exposed from the surface of the sheet-like adhesive (the adhesion layer 75B). Alternatively, the adhesion layer 75B may be formed of a flexible adhesive, and after applying the adhesive to the second surface (the lower surface in the figure) of the layer 75A, by removing the adhesive applied to the surface of the connection members 73 using a squeeze, the connection members 73 may be exposed from the surface of the adhesion layer 75B. Subsequently, a non-conductive surface layer (not illustrated) that covers the plurality of separated island-shaped conductors 71A and the first surface (the upper surface in the figure) of the layer 75A is provided as necessary.

For example, the structure 30 can be manufactured in the above-described manner. After the structure 30 is manufactured, by attaching the structure 30 to be in contact with the inner wall surface 11 of the frame 10 manufactured according to the related art, the state illustrated in FIG. 5 is obtained. In this case, the connection members 73 are attached to be in contact with the inner wall surface 11.

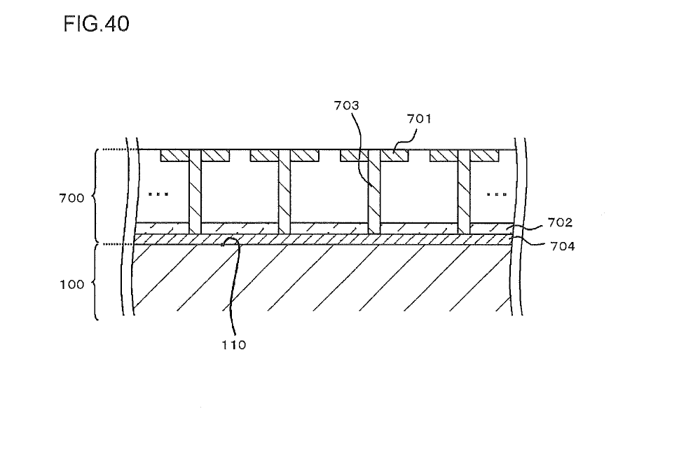

Here, by just attaching a sheet having the EBG structure illustrated in FIGS. 6 and 7 to the inner wall surface 11, the above-described effects are not realized. Hereinafter, the reasons therefor will be described with reference to FIG. 40.

FIG. 40 is a cross-sectional view illustrating a state where a sheet 700 having the EBG structure illustrated in FIGS. 6 and 7 is attached to an inner wall surface 110 of a frame 100. The sheet 700 illustrated in FIG. 40 includes a sheet-like conductor 702, a plurality of separated island-shaped conductors 701, and a plurality of connection members 703.

As illustrated in FIG. 40, in general, since the sheet 700 includes a layer 704 formed of an insulating adhesive in order to secure adhesion properties in relation to a member to be attached. As illustrated in FIG. 40, the adhesive layer 704 is positioned between the sheet-like conductor 702 and the inner wall surface 110 in a state where the sheet 700 having the EBG structure is attached to the inner wall surface 110 and creates a state where the sheet-like conductor 702 and the inner wall surface 110 are electrically isolated. In this way, in a state where the inner wall surface 110 and the EBG structure are electrically isolated, it is not possible to suppress propagation of noise on the surface of the inner wall surface 110.

The electronic apparatus according to the present embodiment solves the above-described problem.

Specifically, as illustrated in FIG. 5, in the electronic apparatus according to the present embodiment, the inner wall surface 11 constitutes a portion of the EBG structure. In such a case, as described above, the inner wall surface 11 will not be electrically isolated from the EBG structure. This assumption is true for the following embodiments.

### Second Embodiment

An electronic apparatus according to the present embodiment is based on the configuration of the electronic apparatus according to the first embodiment, except that the configuration of the structure 30 is partially different. The other configurations are the same as those of the electronic apparatus of the first embodiment, and description thereof will not be provided.

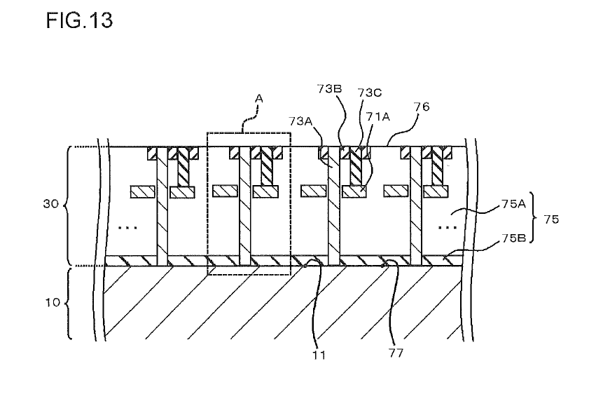

FIG. 13 is a cross-sectional view schematically illustrating an example of a structure 30 that is in contact with an inner wall surface 11 of a frame 10 according to the present embodiment. The illustrated structure 30 is based on the configuration of the structure 30 (see FIG. 5) of the first embodiment except that the configuration of a connection member 73 (73A, 73B, and 73C) is different. The other configurations are the same as those of the first embodiment, and description thereof will not be provided.

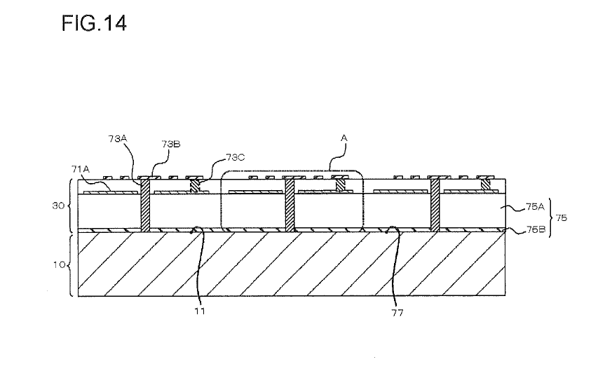

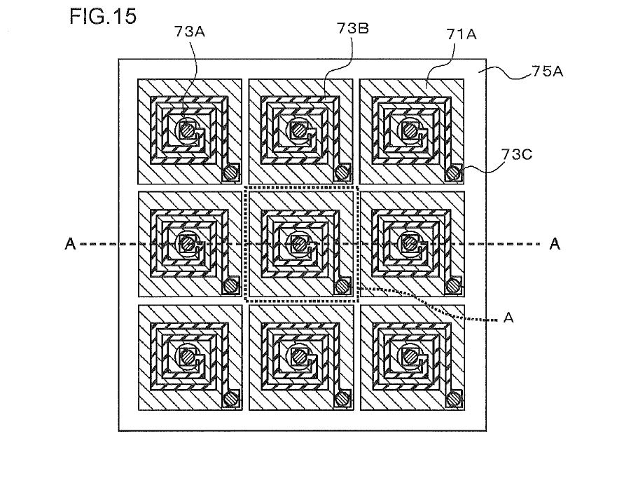

The connection member 73 according to the present embodiment includes a first conductive connection member 73A, a second conductive connection member 73B, and a third conductive connection member 73C. The first connection member 73A has a configuration in which one end thereof penetrates through a surface 77 of a dielectric material layer 75 to be in contact with the inner wall surface 11, and is electrically connected to the second connection member 73B via the other end. The first connection member 73A passes through a hole formed in the island-shaped conductor 71A in a state where the first connection member 73A is not in contact with the island-shaped conductor 71A. The second connection member 73B is electrically connected to the first connection member 73A and is provided to face the island-shaped conductor 71A. A plan-view shape of the second connection member 73B may be a straight line, a curved line, a spiral shape, or other shapes. The second connection member 73B is positioned on a side opposite to the inner wall surface 11 with the island-shaped conductor 71A interposed therebetween. The third connection member 73C is electrically connected to the second connection member 73B via one end thereof and is electrically connected to the island-shaped conductor 71A via the other end that extends toward the surface 77 of the dielectric material layer 75. Here, an example in which the second connection member 73B has a spiral shape is illustrated in FIGS. 14 and 15. FIG. 14 is a cross-sectional view along line A-A of FIG. 15, and FIG. 15 is a plan view of FIG. 14 when seen from top to bottom. In FIGS. 14 and 15, in order to make the configuration more clearly understood, respective constituent components are depicted by hatched lines different from those used in the other figures (FIG. 5 and the like).

Here, in the present embodiment, the inner wall surface 11 and the structure 30 also form an EBG structure. However, the EBG structure formed in the present embodiment is different from the EBG structure described in the first embodiment.

In the EBG structure (see FIGS. 13 to 15) formed in the present embodiment, a unit cell A includes one island-shaped conductor 71A, the connection member 73 (73A, 73B, and 73C) provided so as to face the island-shaped conductor 71A, and a partial area of the inner wall surface 11 including an area that faces the island-shaped conductor 71A. The EBG structure is a short stub-type EBG structure in which a microstrip line that is formed to include the connection member 73B functions as a short stub. Specifically, the connection member 73A forms an inductance. Moreover, the connection member 73B is electrically coupled with the facing island-shaped conductor 71A to form a microstrip line in which the island-shaped conductor 71A is used as a return path. One end of the microstrip line is configured as a short end due to the third connection member 73C so as to function as a short stub.

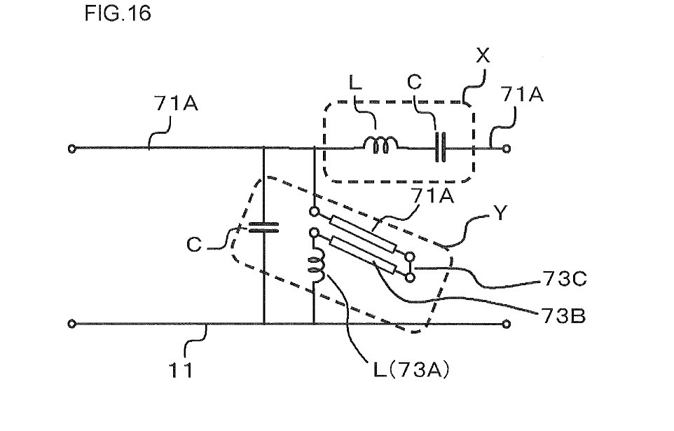

FIG. 16 is an equivalent circuit diagram of the unit cell A of the EBG structure (see FIGS. 13 to 15) formed in the present embodiment. As illustrated in FIG. 16, the unit cell A includes an impedance portion X and an admittance portion Y. The impedance portion X includes a capacitance C generated between the neighboring island-shaped conductors 71A and an inductance L created by the island-shaped conductor 71A. The admittance portion Y includes a capacitance C created by the inner wall surface 11 and the island-shaped conductor 71A, an inductance L created by the first connection member 73A, and a short stub that is formed to include the second connection member 73B (transmission line) and the third connection member 73C.

In general, it is known that an EBG structure creates an electromagnetic bandgap in a frequency range where the impedance portion X is capacitive and the admittance portion Y is inductive. In the short stub-type EBG structure illustrated in FIGS. 13 to 15, by increasing the stub length of the short stub, it is possible to shift the frequency range where the admittance portion Y is inductive toward a low frequency range. Thus, it is possible to shift the bandgap range toward a low frequency range. Although the short stub-type EBG structure requires a stub length for shifting the bandgap range toward a low frequency range, since the short stub-type EBG structure does not necessarily require a certain area, it is possible to decrease the size of the unit cell.

According to the EBG structure, it is possible to suppress propagation of noise current on the surface of the inner wall surface 11 and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures may be disposed repeatedly (for example, periodically). By doing so, it is possible to broaden the bandgap range.

In the EBG structure formed by the structure 30 of the present embodiment, it is possible to form various inductances L and capacitances C as illustrated in FIG. 16 by the configuration of the characteristic connection member 73 (73A, 73B, and 73C). As a result, it is possible to obtain the inductance L and the capacitance C required for suppressing propagation of noise in a desired frequency range without increasing the size of the island-shaped conductor 71A and the connection member 73 (73A, 73B, and 73C) more than necessary. That is, it is possible to make the size of the unit cell A relatively small. In such a case, it is possible to increase the number of unit cells A per unit area and to suppress propagation of noise more effectively.

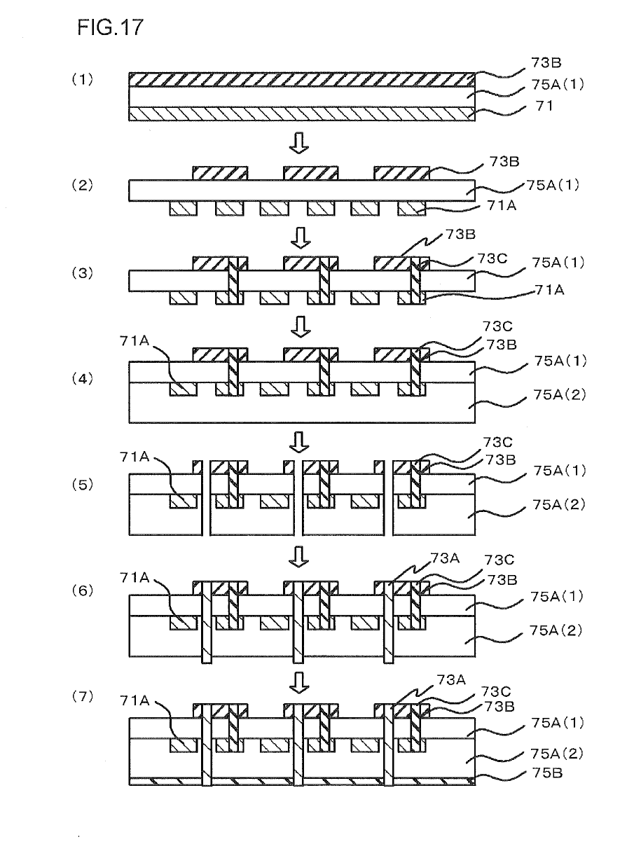

Next, an example of a method of manufacturing the electronic apparatus according to the present embodiment will be described with reference to FIG. 17. FIG. 17 is a cross-sectional view illustrating an example of the steps of manufacturing the structure 30 according to the present embodiment.

First, as illustrated in (1), a copper foil 73B is formed on a first surface (an upper surface in the figure) of a substrate (layer 75A(1)) such as a glass epoxy substrate or a fluorine resin substrate, and a copper foil 71 is formed on a second surface (the lower surface in the figure). Subsequently, as illustrated in (2), a portion of the copper foil 71 is selectively etched by photolithography and etching to form a pattern (the plurality of separated island-shaped conductors 71A). Moreover, a portion of the copper foil 73B is selectively etched by photolithography and etching to form a pattern (the second connection member 73B). The island-shaped conductor 71A is formed in a pattern in which a hole for passing the first connection member 73A therethrough is provided. This hole is provided to be greater than the diameter of the first connection member 73A.

After that, holes that penetrate through the second connection member 73B, the layer 75A(1), and the island-shaped conductor 71A are formed by drilling. Penetration pins (the third connection members 73C) formed of metal such as copper, aluminum, or stainless steel are inserted into the holes to obtain the state illustrated in (3).

Subsequently, as illustrated in (4), a dielectric material layer 75A(2) is further formed on the second surface (the lower surface in the figure) of the layer 75A(1). For example, a new flexible substrate (the layer 75A(2)) such as a glass epoxy substrate or a fluorine resin substrate may be prepared, and a first surface (an upper surface in the figure) of the substrate (the layer 75A(2)) may be attached to the second surface (the lower surface in the figure) of the layer 75A(1). In this way, in the present embodiment, the island-shaped conductor 71A (the first conductor) is provided in an inner portion of the dielectric material layer that includes the layers 75A(1) and 75A(2).

After that, as illustrated in (5), holes that penetrate through the second connection member 73B, the layers 75A(1) and 75A(2), and the island-shaped conductor 71A are formed using a drill. The holes have a smaller diameter than the holes formed in the island-shaped conductor 71A in (2) and are formed by allowing a drill to pass through the holes in a state where the drill does not make contact with the island-shaped conductor 71A. After that, as illustrated in (6), penetration pins (the first connection members 73A) formed of metal such as copper, aluminum, or stainless steel are inserted into the holes formed in (5).

After that, as illustrated in (7), the adhesion layer 75B is formed on the second surface (the lower surface in the figure) of the layer 75A(2). The adhesion layer 75B is formed such that the first connection members 73A penetrate through the adhesion layer 75B and are exposed. The same means as the means described in the first embodiment can be used as specific means for forming in this manner. Subsequently, a non-conductive surface layer (not illustrated) that covers the second connection member 73B and the first surface (the upper surface in the figure) of the layer 75A(1) is provided as necessary.

For example, the structure 30 can be manufactured in the above-described manner. After the structure 30 is manufactured, by attaching the structure 30 to be in contact with the inner wall surface 11 of the frame 10 manufactured according to the related art, the state illustrated in FIG. 13 is obtained. In this case, the first connection members 73A are attached to be in contact with the inner wall surface 11.

### Third Embodiment

An electronic apparatus according to the present embodiment is based on the configuration of the electronic apparatus according to the first embodiment, except that the configuration of the structure 30 is partially different.

The other configurations are the same as those of the electronic apparatus of the first embodiment, and description thereof will not be provided.

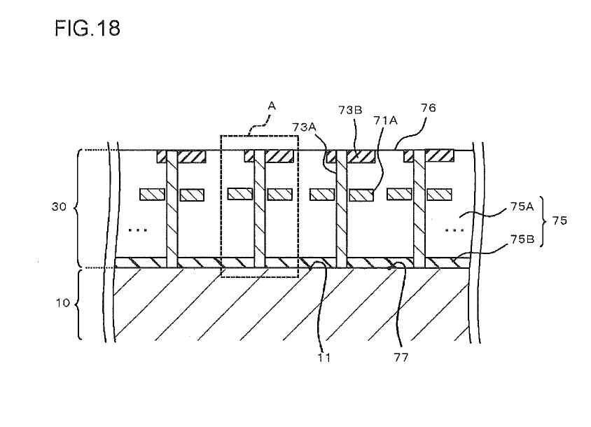

FIG. 18 is a cross-sectional view schematically illustrating an example of a structure 30 that is in contact with an inner wall surface 11 of a frame 10 according to the present embodiment. The illustrated structure 30 is based on the configuration of the structure 30 (see FIG. 5) of the first embodiment except that the configuration of a connection member 73 (73A and 73B) is different. The other configurations are the same as those of the first embodiment, and description thereof will not be provided.

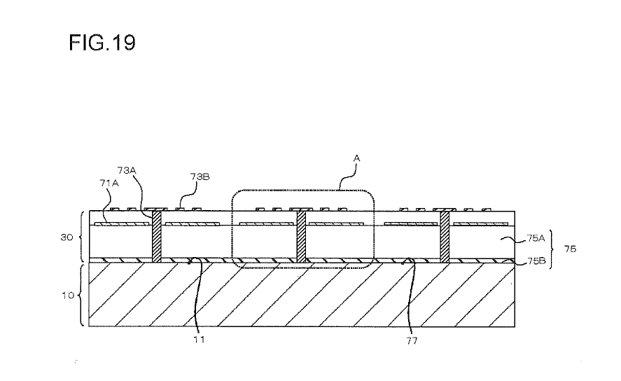

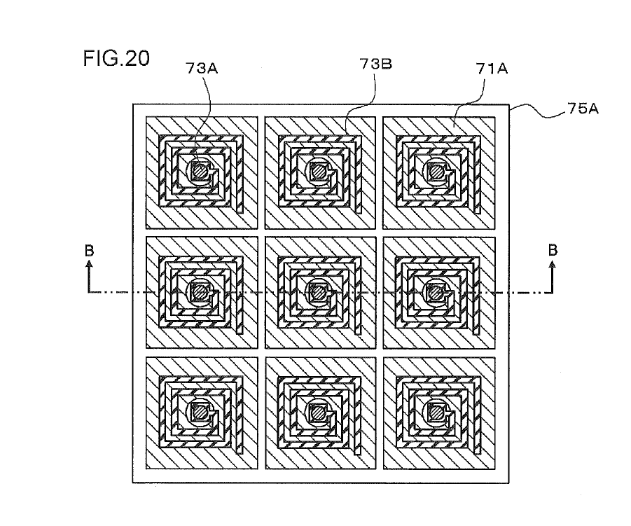

The connection member 73 according to the present embodiment includes a first conductive connection member 73A and a second conductive connection member 73B. The first connection member 73A has a configuration in which one end thereof penetrates through a surface 77 of a dielectric material layer 75 to be in contact with the inner wall surface 11, and is electrically connected to the second connection member 73B via the other end. The first connection member 73A passes through a hole formed in the island-shaped conductor 71A in a state where the first connection member 73A is not in contact with the island-shaped conductor 71A. The second connection member 73B is electrically connected to the first connection member 73A and is provided so as to face the island-shaped conductor 71A. A plan-view shape of the second connection member 73B may be a straight line, a curved line, a spiral shape, or other shapes. The second connection member 73B is positioned on a side opposite to the inner wall surface 11 with the island-shaped conductor 71A interposed therebetween. Moreover, the other end of the second connection member 73B is an open end. Here, an example in which the second connection member 73B has a spiral shape is illustrated in FIGS. 19 and 20. FIG. 19 is a cross-sectional view along line A-A of FIG. 20, and FIG. 20 is a plan view of FIG. 19 when seen from top to bottom. In FIGS. 19 and 20, in order to make the configuration more clearly understood, respective constituent components are depicted by hatched lines different from those used in the other figures (FIG. 5 and the like).

Here, in the present embodiment, the inner wall surface 11 and the structure 30 also form an EBG structure. However, the EBG structure formed in the present embodiment is different from the EBG structure described in the first and second embodiments.

In the EBG structure formed in the present embodiment, a unit cell A includes one island-shaped conductor 71A, the connection member 73 (73A and 73B) provided so as to correspond to the island-shaped conductor 71A, and a partial area of the inner wall surface 11 including an area that faces the island-shaped conductor 71A. The EBG structure is an open stub-type EBG structure in which a microstrip line that is formed to include the connection member 73B functions as an open stub. Specifically, the connection member 73A forms an inductance. Moreover, the connection member 73B is electrically coupled with the facing island-shaped conductor 71A to form a microstrip line in which the island-shaped conductor 71A is used as a return path. One end of the microstrip line is configured as an open end so as to function as an open stub.

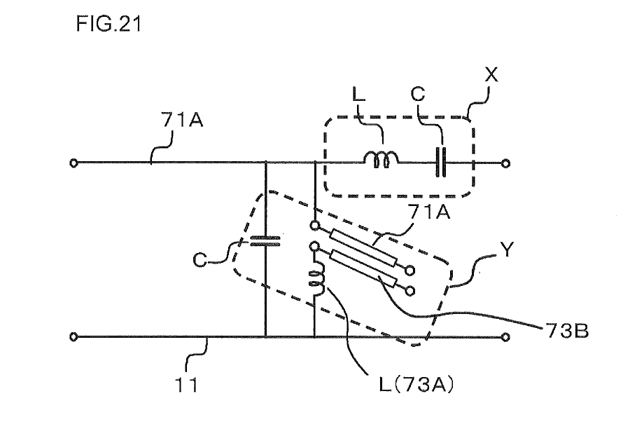

FIG. 21 is an equivalent circuit diagram of the unit cell A of the EBG structure (see FIGS. 18 to 20) formed in the present embodiment. As illustrated in FIG. 21, the unit cell A includes an impedance portion X and an admittance portion Y. The impedance portion X includes a capacitance C generated between the neighboring island-shaped conductors 71A and an inductance L created by the island-shaped conductor 71A. The admittance portion Y includes a capacitance C created by the inner wall surface 11 and the island-shaped conductor 71A, an inductance L created by the first connection member 73A, and an open stub that is formed to include the second connection member 73B (transmission line).

In general, it is known that an EBG structure creates an electromagnetic bandgap in a frequency range where the impedance portion X is capacitive and the admittance portion Y is inductive. In the open stub-type EBG structure illustrated in FIGS. 18 to 20, by increasing the stub length of the open stub, it is possible to shift the frequency range where the admittance portion Y is inductive toward a low frequency range. Thus, it is possible to shift the bandgap range toward a low frequency range. Although the open stub-type EBG structure requires a stub length for shifting the bandgap range toward a low frequency range, since the open stub-type EBG structure does not necessarily require a certain area, it is possible to decrease the size of the unit cell.

According to the EBG structure, it is possible to suppress propagation of noise current on the surface of the inner wall surface 11 and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures maybe disposed repeatedly (for example, periodically). By doing so, it is possible to broaden the bandgap range.

In the EBG structure formed by the structure 30 of the present embodiment, it is possible to form various inductances L and capacitances C as illustrated in FIG. 21 by the configuration of the characteristic connection member 73 (73A and 73B). As a result, it is possible to obtain the inductance L and the capacitance C required for suppressing propagation of noise in a desired frequency range without increasing the size of the island-shaped conductor 71A and the connection member 73 (73A and 73B) more than necessary. That is, it is possible to make the size of the unit cell A relatively small. In such a case, it is possible to increase the number of unit cells A per unit area and to suppress propagation of noise more effectively.

A method of manufacturing the electronic apparatus according to the present embodiment can be realized according to the method of manufacturing the electronic apparatus described in the second embodiment. Thus, description thereof will not be provided.

### Fourth Embodiment

An electronic apparatus according to the present embodiment is based on the configuration of the electronic apparatus according to the first embodiment, except that the configuration of the structure 30 is partially different. The other configurations are the same as those of the electronic apparatus of the first embodiment, and description thereof will not be provided.

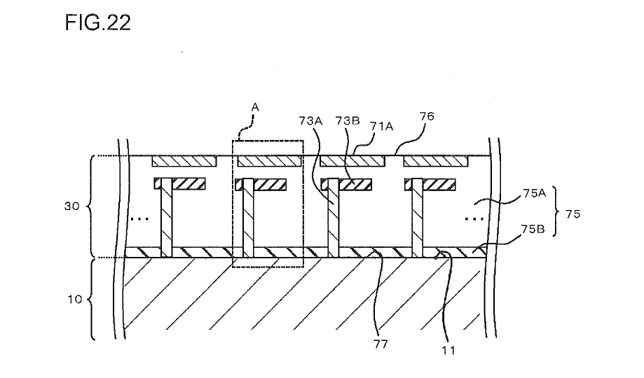

FIG. 22 is a cross-sectional view schematically illustrating an example of a structure 30 that is in contact with an inner wall surface 11 of a frame 10 according to the present embodiment. The illustrated structure 30 is based on the configuration of the structure 30 (see FIG. 5) of the first embodiment except that the configuration of a connection member 73 (73A and 73B) is different. The other configurations are the same as those of the first embodiment, and description thereof will not be provided.

The connection member 73 according to the present embodiment includes a first conductive connection member 73A and a second conductive connection member 73B. The first connection member 73A has a configuration in which one end thereof penetrates through a surface 77 of a dielectric material layer 75 to be in contact with the inner wall surface 11, and is electrically connected to the second connection member 73B via the other end. The first connection member 73A is not in contact with the island-shaped conductor 71A. The second connection member 73B is electrically connected to the first connection member 73A and is provided so as to face the island-shaped conductor 71A. A plan-view shape of the second connection member 73B may be a straight line, a curved line, a spiral shape, or other shapes. The second connection member 73B is positioned closer to the inner wall surface 11 than the island-shaped conductor 71A. Moreover, the other end of the second connection member 73B is an open end.

Here, in the present embodiment, the inner wall surface 11 and the structure 30 also form an EBG structure. However, the EBG structure formed in the present embodiment is different from the EBG structure described in the first to third embodiments.

In the EBG structure formed in the present embodiment, a unit cell A includes one island-shaped conductor 71A, the connection member 73 (73A and 73B) provided so as to correspond to the island-shaped conductor 71A, and a partial area of the inner wall surface 11 including an area that faces the island-shaped conductor 71A. The EBG structure is an open stub-type EBG structure in which a microstrip line that is formed to include the connection member 73B functions as an open stub. Specifically, the connection member 73A forms an inductance. Moreover, the connection member 73B is electrically coupled with the facing island-shaped conductor 71A to form a microstrip line in which the island-shaped conductor 71A is used as a return path. One end of the microstrip line is configured as an open end so as to function as an open stub.

The equivalent circuit diagram of the unit cell A illustrated in FIG. 22 is the same as the equivalent circuit diagram (FIG. 21) described in the third embodiment. Thus, description thereof will not be provided.

According to the EBG structure, it is possible to suppress propagation of noise current on the surface of the inner wall surface 11 and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures may be disposed repeatedly (for example, periodically). By doing so, it is possible to broaden the bandgap range.

In the EBG structure formed by the structure 30 of the present embodiment, it is possible to form various inductances L and capacitances C as illustrated in FIG. 21 by the configuration of the characteristic connection member 73 (73A and 73B). As a result, it is possible to obtain the inductance L and the capacitance C required for suppressing propagation of noise in a desired frequency range without increasing the size of the island-shaped conductor 71A and the connection member 73 (73A and 73B) more than necessary. That is, it is possible to make the size of the unit cell A relatively small. In such a case, it is possible to increase the number of unit cells A per unit area and to suppress propagation of noise more effectively.

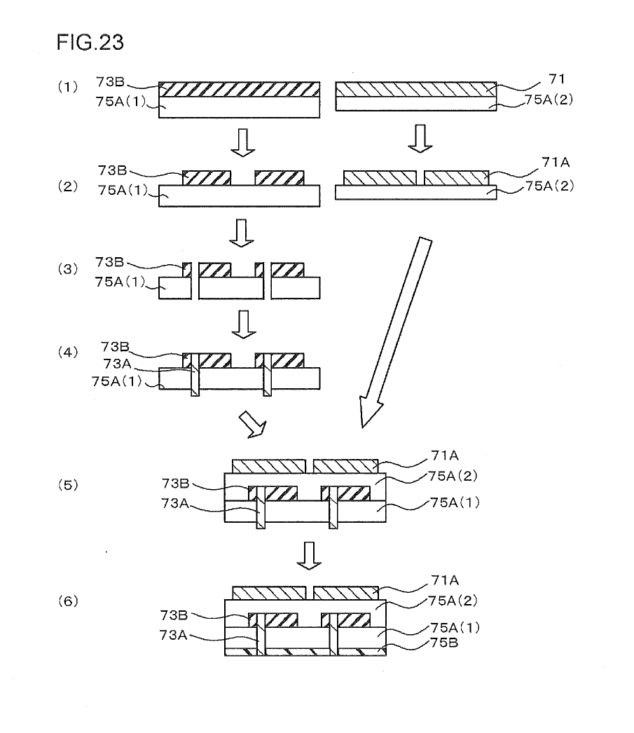

Next, an example of a method of manufacturing the structure 30 according to the present embodiment will be described with reference to FIG. 23. FIG. 23 is a cross-sectional view illustrating an example of the steps of manufacturing the structure 30 according to the present embodiment.

First, as illustrated in (1), a copper foil 73B is formed on a first surface (an upper surface in the figure) of a substrate (the layer 75A (1)) such as a glass epoxy substrate or a fluorine resin substrate. Moreover, a copper foil 71 is formed on a first surface (an upper surface in the figure) of another flexible substrate (the layer 75A (2))such as a glass epoxy substrate or a fluorine resin substrate. Subsequently, as illustrated in (2), a portion of the copper foil 73B is selectively etched by photolithography and etching to form a pattern (the second connection member 73B). Moreover, a portion of the copper foil 71 is selectively etched by photolithography and etching to form a pattern (the plurality of separated island-shaped conductors 71A).

After that, as illustrated in FIG. 3), holes that penetrate through the second connection member 73B and the layer 75A(1) are formed by drilling. Subsequently, as illustrated in (4), penetration pins (the first connection members 73A) formed of metal such as copper, aluminum, or stainless steel are inserted into the holes formed in (3).

After that, as illustrated in (5), a second surface (a lower surface in the figure) of the layer 75A(2) is attached to be in contact with a first surface (an upper surface in the figure) of the layer 75A(1). Subsequently, as illustrated in (6), the adhesion layer 75B is formed on the second surface (the lower surface in the figure) of the layer 75A (1). The adhesion layer 75B is formed such that the first connection members 73A penetrate through the adhesion layer 75B and are exposed. The same means as the means described in the first embodiment can be used as specific means for forming in this manner. Subsequently, a non-conductive surface layer (not illustrated) that covers the plurality of separated island-shaped conductors 71A and the first surface of the layer 75A(2) is provided as necessary.

For example, the structure 30 can be manufactured in the above-described manner. After the structure 30 is manufactured, by attaching the structure 30 to be in contact with the inner wall surface 11 of the frame 10 manufactured according to the related art, the state illustrated in FIG. 22 is obtained. In this case, the first connection members 73A are attached to be in contact with the inner wall surface 11.

### Fifth Embodiment

An electronic apparatus according to the present embodiment is based on the configuration of the electronic apparatus according to the first embodiment, except that the configuration of the structure 30 is partially different. The other configurations are the same as those of the electronic apparatus of the first embodiment, and description thereof will not be provided.

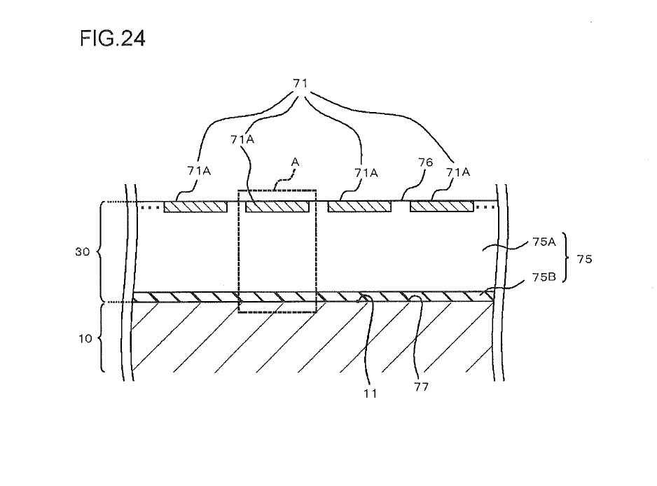

FIG. 24 is a cross-sectional view schematically illustrating an example of a structure 30 that is in contact with an inner wall surface 11 of a frame 10 according to the present embodiment. The illustrated structure 30 according to the present embodiment includes a dielectric material layer 75 and first conductors 71 that are formed on one surface 76 (a surface 76 on a side opposite to a surface 77 that is in contact with the inner wall surface 11) of the dielectric material layer 75 and have a repeated structure (for example, a periodic structure) in at least a partial area.

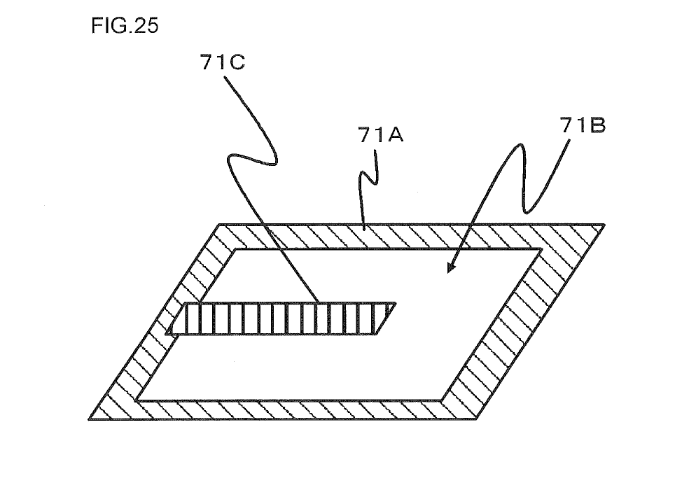

As the repeated structure of the first conductors 71, a structure in which a plurality of separated island-shaped conductors 71A is provided repeatedly (for example, periodically) can be considered. Moreover, openings 71B are formed in a part or an entire part of the plurality of island-shaped conductors 71A as illustrated in an enlarged perspective view of FIG. 25. When the openings 71B are formed in apart of the plurality of island-shaped conductors 71A, the openings 71B are preferably formed periodically. An interconnect 71C of which one end is electrically connected to the island-shaped conductor 71A is formed in the opening 71B. The size of the opening 71B, the length and thickness of the interconnect 71C, and the like are design matters that are determined according to the frequency of noise of which the propagation is to be suppressed. Such a first conductor 71 is provided so as to face the inner wall surface 11 of the frame 10. The first conductor 71 may be provided in an inner portion of the dielectric material layer 75 so as to face the inner wall surface 11.

A portion of the dielectric material layer 75 is formed of an adhesion layer 75B that is attached to the inner wall surface 11.

Here, in the present embodiment, the inner wall surface 11 and the structure 30 also form an EBG structure. However, the EBG structure formed in the present embodiment is different from the EBG structure described in the first to fourth embodiments.

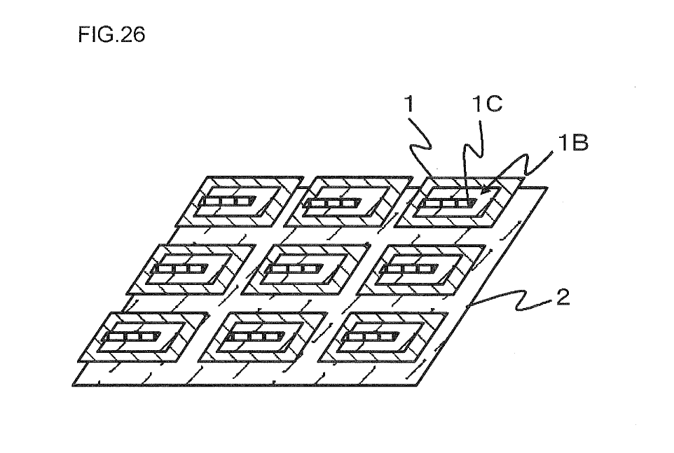

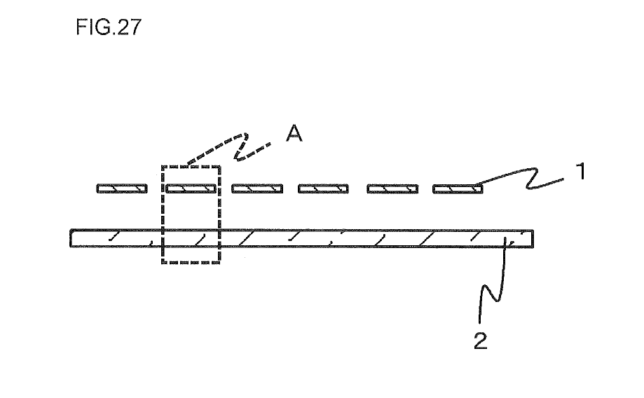

FIGS. 26 and 27 schematically illustrate an EBG structure that includes the inner wall surface 11 according to the present embodiment and the structure 30. FIG. 26 is a perspective view schematically illustrating the configuration of the EBG structure, and FIG. 27 is a side view of the EBG structure of FIG. 26. A sheet-like conductor 2 corresponds to the inner wall surface 11, and an island-shaped conductor 1 corresponds to the island-shaped conductor 71A of the structure 30.

The EBG structure illustrated in FIGS. 26 and 27 includes the sheet-like conductor 2, the plurality of separated island-shaped conductors 1, an opening 1B formed in the island-shaped conductors 1, and an interconnect 1C formed in the opening 1B. The plurality of island-shaped conductors 1 is disposed in areas that overlap the sheet-like conductor 2 in a plan view and is disposed at a position separated from the sheet-like conductor 2 with a dielectric material layer (not illustrated) interposed. Moreover, the plurality of island-shaped conductors 1 are arranged periodically. The opening 1B is formed in the plurality of island-shaped conductors 1, and the interconnect 1C of which one end is electrically connected to the island-shaped conductor 1 is formed in the opening 1B. The interconnect 1C functions as an open stub, and a portion of the sheet-like conductor 2 facing the interconnect 1C and the interconnect 1C forma transmission line (for example, a microstrip line).

In the EBG structure, a unit cell A includes one island-shaped conductor 1, the interconnect 1C formed in the opening 1B of the island-shaped conductor 1, and a partial area of the sheet-like conductor 2 including areas that face the island-shaped conductor 1 and the interconnect 1C. The unit cells A are disposed periodically, whereby the structure functions as a metamaterial (for example, an EBG). In the example illustrated in FIGS. 26 and 27, the unit cells have a two-dimensional arrangement in a plan view.

The plurality of unit cells A has the same structure and is disposed in the same direction. The island-shaped conductor 1 and the opening 1B are in a square shape and are disposed so that the centers thereof overlap each other. The interconnect 1C extends from approximately the center of one side of the opening 1B in a direction approximately vertical to the side.

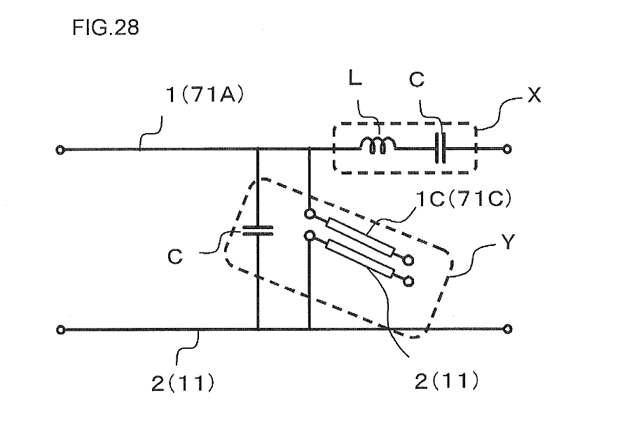

FIG. 28 is an equivalent circuit diagram of the unit cell A illustrated in FIGS. 26 and 27. As illustrated in FIG. 28, a capacitance C is formed between the sheet-like conductor 2 and the island-shaped conductor 1. Moreover, a capacitance C is formed between the neighboring island-shaped conductors 1. Moreover, an inductance L is formed in the island-shaped conductor 1 that has the opening 1B.

Moreover, as described above, the interconnect 1C functions as an open stub, and the portion of the sheet-like conductor 2 facing the interconnect 1C and the interconnect 1C forma transmission line (for example, a microstrip line). The other end of the transmission line is an open end.

According to the EBG structure, it is possible to suppress propagation of noise on the surface of the sheet-like conductor 2. Moreover, since the neighboring island-shaped conductors 1 form a capacitance C, it is possible to suppress propagation of noise near the EBG structure.

In the electronic apparatus of the present embodiment in which the inner wall surface 11 and the structure 30 form the EBG structure described above, it is possible to suppress propagation of noise current in an area of the inner wall surface 11 where the structure 30 is formed and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures maybe disposed repeatedly (for example, periodically). By doing so, it is possible to broaden the bandgap range.

In the electronic apparatus of the present embodiment, unlike the first to fourth embodiments, since the connection member 73 is not provided, it is not necessary to provide means for securing electrical connection between the connection member 73 and the inner wall surface 11. As a result, quality stability increases.

Next, an example of a method of manufacturing the electronic apparatus according to the present embodiment will be described.

In the structure 30 according to the present embodiment, as illustrated in (1) of FIG. 12, a copper foil 71 is formed on a first surface of a substrate (the layer 75A) such as a glass epoxy substrate or a fluorine resin substrate. After that, as illustrated in (2), a portion of the copper foil 71 is selectively etched by photolithography and etching to form a pattern (the plurality of separated island-shaped conductors 71A). By the photolithography and etching, the island-shaped conductors 71A are formed in the pattern illustrated in FIG. 25. After that, an adhesion layer 75B is formed on the second surface of the layer 75A to obtain the structure 30. The adhesion layer 75B can be formed according to the first embodiment.

For example, the structure 30 can be manufactured in the above-described manner. After the structure 30 is manufactured, the structure 30 is attached to be in contact with the inner wall surface 11 of the frame 10 manufactured according to the related art, whereby the state illustrated in FIG. 24 is obtained.

### Sixth Embodiment

An electronic apparatus according to the present embodiment is based on the configuration of the electronic apparatus according to the fifth embodiment, except that the configuration of the structure 30 is partially different. Specifically, the configuration within the opening 71B of the island-shaped conductor 71A is different. The other configurations are the same as those of the electronic apparatus of the fifth embodiment, and description thereof will not be provided.

A cross-sectional view schematically illustrating an example of the structure 30 that is in contact with the inner wall surface 11 of the frame 10 according to the present embodiment is the same as that of the fifth embodiment (see FIG. 24).

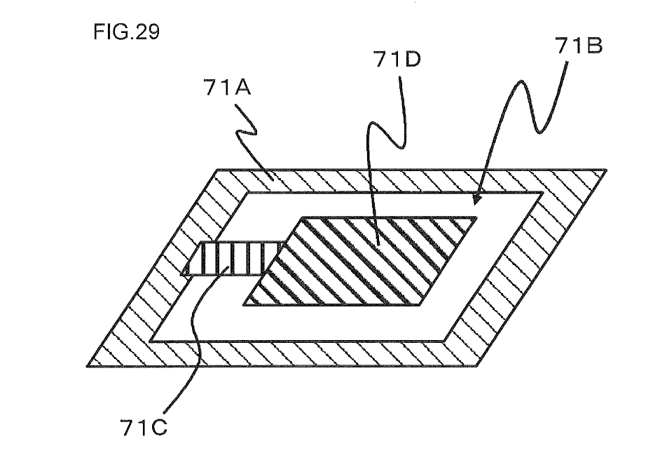

Next, an enlarged perspective view of the island-shaped conductor 71A according to the present embodiment is illustrated in FIG. 29. In the structure 30 according to the present embodiment, an opening 71B illustrated in FIG. 29 is formed in a part or an entire part of the plurality of island-shaped conductors 71A, and an opening conductor 71D and an interconnect 71C are formed in a part or an entire part of the openings 71B. The interconnect 71C electrically connects the island-shaped conductor 71A and the opening conductor 71D.

Here, in the present embodiment, the inner wall surface 11 and the structure 30 also form an EBG structure. However, the EBG structure formed in the present embodiment is different from the EBG structure described in the first to fifth embodiments.

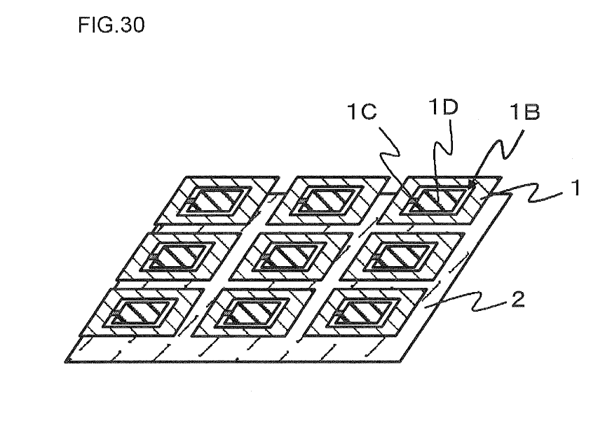

FIG. 30 schematically illustrates an EBG structure that includes the inner wall surface 11 according to the present embodiment and the structure 30. FIG. 30 is a perspective view schematically illustrating the configuration of the EBG structure. A side view of the EBG structure is the same as that of the fifth embodiment (see FIG. 27). A sheet-like conductor 2 corresponds to the inner wall surface 11, and an island-shaped conductor 1 corresponds to the island-shaped conductor 71A of the structure 30.

The EBG structure illustrated in FIGS. 27 and 30 includes the sheet-like conductor 2, the plurality of separated island-shaped conductors 1, an opening 1B formed in the island-shaped conductors 1, and an interconnect 1C and an opening conductor 19 formed in the opening 1B. The plurality of island-shaped conductors 1 is disposed in areas that overlap the sheet-like conductor 2 in a plan view and is disposed at a position separated from the sheet-like conductor 2 with a dielectric material layer (not illustrated) interposed. Moreover, the plurality of island-shaped conductors 1 are arranged periodically. The opening 1B is formed in the plurality of island-shaped conductors 1, and the interconnect 1C of which one end is electrically connected to the island-shaped conductor 1 is formed in the opening 1B. Further, the opening conductor 1D that is electrically connected to the other end of the interconnect 1C is formed in the opening 1B.

In the EBG structure, a unit cell A includes one island-shaped conductor 1, the interconnect 1C and the opening conductor 1D formed in the opening 1B of the island-shaped conductor 1, and a partial area of the sheet-like conductor 2 including an area that faces the island-shaped conductor 1, the interconnect 1C, and the opening conductor 1D. The unit cells A are disposed periodically, whereby the structure functions as a metamaterial (for example, an EBG). In the example illustrated in FIG. 30, the unit cells A have a two-dimensional arrangement in a plan view.

The plurality of unit cells A has the same structure and is disposed in the same direction. The island-shaped conductor 1, the opening 1B, and the opening conductor 1D are in a square shape and are disposed so that the centers thereof overlap each other. The interconnect 10 extends from approximately the center of one side of the opening 1B in a direction approximately vertical to the side. Moreover, the interconnect 10 electrically connects the center of a first side of the opening conductor 1D and the center of a side of the opening 1B facing the first side of the opening conductor 1D.

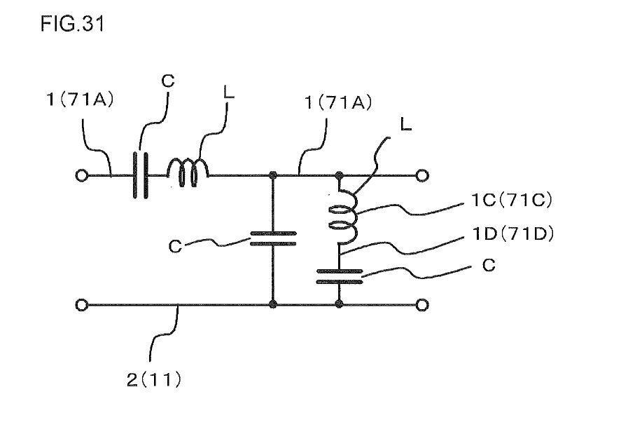

FIG. 31 is an equivalent circuit diagram of the unit cell A of the EBG structure illustrated in FIG. 30. As illustrated in FIG. 31, a capacitance C is formed between the island-shaped conductor 1 and the sheet-like conductor 2. Moreover, a capacitance C is formed between the neighboring island-shaped conductors 1. Further, a capacitance C is also formed between the opening conductor 1D and the sheet-like conductor 2. Moreover, an inductance L is formed in the island-shaped conductor 1 that has the opening 1B. Further, the interconnect 10 that electrically connects the island-shaped conductor 1 and the opening conductor 1D has an inductance L.

According to the EBG structure, it is possible to suppress propagation of noise current on the surface of the sheet-like conductor 2. Moreover, since the neighboring island-shaped conductors 1 form a capacitance C, it is possible to suppress propagation of noise near the EBG structure.

In the electronic apparatus of the present embodiment in which the inner wall surface 11 and the structure 30 form the EBG structure described above, it is possible to suppress propagation of noise current in an area of the inner wall surface 11 where the structure 30 is formed and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures may be disposed repeatedly (for example, periodically). By doing so, it is possible to broaden the bandgap range.

In the electronic apparatus of the present embodiment, unlike the first to fourth embodiments, since the connection member 73 is not provided, it is not necessary to provide means for securing electrical connection between the connection member 73 and the inner wall surface 11. As a result, quality stability increases.

A method of manufacturing the electronic apparatus according to the present embodiment can be realized according to the method of manufacturing the electronic apparatus according to the fifth embodiment, and description thereof will not be provided.

### Seventh Embodiment

An electronic apparatus according to the present embodiment is based on the configuration of the electronic apparatus according to the first to sixth embodiments, except that the configuration of the structure 30 is partially different. The other configurations are the same as those of the electronic apparatus of the first to sixth embodiments, and description thereof will not be provided.

In the first to sixth embodiments, the structure 30 includes the adhesion layer 75B and is formed in a sheet-like form and attached to the frame 10. In contrast, in the present embodiment, the structure 30 does not have the adhesion layer 75B and is formed to be in contact with the inner wall surface 11 using an existing layer formation technique such as a CVD method (chemical vapor deposition method), a CMP method (chemical mechanical polishing method), photolithography, or etching. In the present embodiment, the dielectric material layer 75 may not have flexible properties, and optional dielectric materials can be used as a material of the dielectric material layer 75. The other configurations are the same as the configurations described in the first to sixth embodiments, and description thereof will not be provided.

According to the electronic apparatus according to the present embodiment, in addition to the effects described in the first to sixth embodiments, it is possible to obtain an effect that the lifespan of the noise propagation suppression function realized by the structure 30 is extended.

That is, in the case of the first to sixth embodiments, there is a concern that the structure 30 may be detached from the inner wall surface 11 of the frame 10 due to a performance lifespan of the adhesion layer 75B (adhesive) of the sheet-like structure 30 or an unexpected cause.

In contrast, in the case of the present embodiment, since the adhesion force between the inner wall surface 11 of the frame 10 and the structure 30 is stronger than that of the first to sixth embodiments, the problem described above is unlikely to occur.

### Eighth Embodiment

An electronic apparatus according to the present embodiment is based on the configuration of the electronic apparatus according to any one of the first to seventh embodiments, except that the configuration of the structure 30 is partially different. The other configurations are the same as those of any one of the first to seventh embodiments, and description thereof will not be provided.

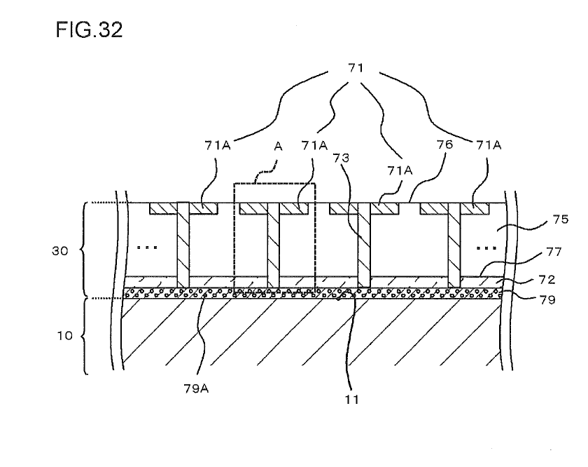

FIG. 32 is a cross-sectional view schematically illustrating an example of a structure 30 that is in contact with an inner wall surface 11 of a frame 10 according to the present embodiment. For example, the structure 30 according to the present embodiment includes a dielectric material layer 75, first conductors 71 that are formed on one surface 76 of the dielectric material layer 75 so as to face second conductors 72 and include a repeated structure (for example, a periodic structure) in at least a partial area, the second conductors 72 that are formed on a surface 77 (a surface on a side opposite to the surface 76) of the dielectric material layer 75, an adhesion layer 79 formed on the second conductors 72, and connection members 73 that are formed in an inner portion of the dielectric material layer 75 so as to electrically connect the first conductors 71 and the second conductors 72. The first conductors 71 may be provided in an inner portion of the dielectric material layer 75 so as to face the second conductors 72.

The configuration of the first conductor 71 illustrated in FIG. 32 is the same as that of the first conductor 71 described in the first embodiment, for example. Moreover, the configuration of the dielectric material layer 75 is the same as that of the dielectric material layer 75 described in the first embodiment except that the dielectric material layer 75 does not have an adhesion layer.

The second conductor 72 is a sheet-like conductor that extends on the surface 77 of the dielectric material layer 75 so as to face a plurality of island-shaped conductors 71A in a plan view. For example, the second conductor 72 can be formed of a material such as copper, for example.

The adhesion layer 79 is provided on a surface (a surface on a side opposite to a surface that is in contact with the dielectric material layer 75) of the second conductor 72 and is in contact with the inner wall surface 11 of the frame 10. That is, the adhesion layer 79 is interposed between the inner wall surface 11 and the second conductor 72. Such an adhesion layer 79 may be formed of natural rubber, an acrylic resin, or silicone.

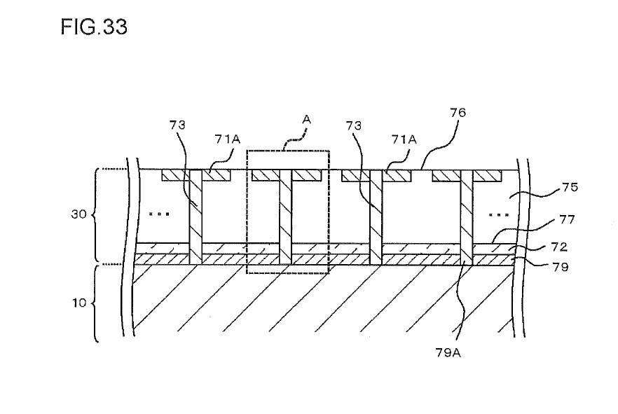

A conduction member 79A is configured to electrically connect the second conductor 72 and the inner wall surface 11. For example, the conduction member 79A may be a plurality of conductive fillers that is mixed into the adhesion layer 79. Alternatively, the conduction member 79A may be a via illustrated in FIG. 33. The via 79A may be provided to be integrated with the connection member 73.

Here, the configuration of the connection member 73 according to the present embodiment is not limited to that illustrated in FIGS. 32 and 33, but the configuration illustrated in FIGS. 13, 14, 15, 18, 19, 20, and 22 may be used, for example. The connection member 73 and the structure 30 illustrated in these figures have been described in the above embodiments, and description thereof will not be provided.

Moreover, in the present embodiment, the connection member 73 may be not provided. In such a case, the opening 71B and the interconnect 71C illustrated in the enlarged perspective view of FIG. 25 are provided in apart or an entire part of the plurality of island-shaped conductors 71A. Moreover, the opening 71B, the interconnect 71C, and the opening conductor 71D illustrated in the enlarged perspective view of FIG. 29 may be provided in a part or an entire part of the plurality of island-shaped conductors 71A.

The island-shaped conductor 71A and the second structure 70 illustrated in these figures have been described in the above embodiments, and description thereof will not be provided.

A method of manufacturing the electronic apparatus according to the present embodiment can be realized according to the above embodiments. Thus, description thereof will not be provided.

In the electronic apparatus according to the present embodiment, the structure 30 has an EBG structure, and means for electrically connecting the EBG structure and the inner wall surface 11 of the frame 10 is provided. According to such an electronic apparatus according to the present embodiment, it is possible to obtain the same effects as the above embodiments. The electronic apparatus according to the present embodiment solves the problem described with reference to FIG. 40 in the first embodiment by providing the conduction member 79A.

### Ninth Embodiment

An electronic apparatus according to the present embodiment is based on the configuration of the electronic apparatus according to the eighth embodiment, except that the configuration of the structure 30 is partially different. The other configurations are the same as those of the electronic apparatus of the first to seventh embodiments, and description thereof will not be provided.

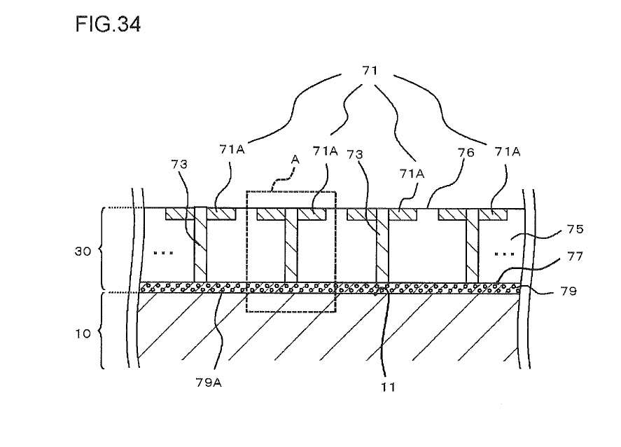

FIG. 34 is a cross-sectional view schematically illustrating an example of a structure 30 that is in contact with an inner wall surface 11 of a frame 10 according to the present embodiment. For example, the structure 30 according to the present embodiment includes a dielectric material layer 75, first conductors 71 that are formed on one surface 76 of the dielectric material layer 75 so as to face the inner wall surface 11 of the frame 10 and include a repeated structure (for example, a periodic structure) in at least a partial area, an adhesion layer 79 that is formed on a surface 77 (a surface on a side opposite to the surface 76) of the dielectric material layer 75, and connection members 73 that are formed in an inner portion of the first dielectric material layer 75 so as to electrically connect the first conductors 71 and the inner wall surface 11. The first conductors 71 may be provided in an inner portion of the dielectric material layer 75 so as to face the inner wall surface 11.

That is, the electronic apparatus according to the present embodiment has a structure such that the second conductor 72 is removed from the configuration (see FIG. 32) of the electronic apparatus according to the eighth embodiment.

A method of manufacturing the electronic apparatus according to the present embodiment can be realized according to the above embodiments. Thus, description thereof will not be provided.

In the electronic apparatus according to the present embodiment, the inner wall surface 11 of the frame 10 and the structure 30 form an EBG structure. According to such an electronic apparatus according to the present embodiment, it is possible to obtain the same effects as the above embodiments.

### Tenth Embodiment

An electronic apparatus according to the present embodiment is based on the configuration of the electronic apparatus according to the first embodiment, except that the configuration of the structure 30 is partially different. The other configurations are the same as those of the electronic apparatus of the first embodiment, and description thereof will not be provided.

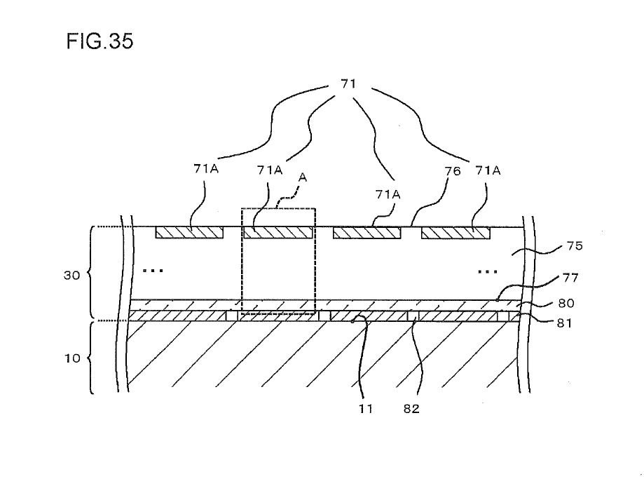

FIG. 35 is a cross-sectional view schematically illustrating an example of a structure 30 that is in contact with an inner wall surface 11 of a frame 10 according to the present embodiment. The structure 30 according to the present embodiment includes a dielectric material layer 75, first conductors 71 that are formed on one surface 76 of the dielectric material layer 75 so as to face a third conductor 80, the third conductor 80 that is formed on a surface 77 (a surface on a side opposite to the surface 76) of the dielectric material layer 75, and a second dielectric material layer 81 that is formed on the third conductor 80.

The first conductors 71 may be provided in an inner portion of the dielectric material layer 75 so as to face the third conductor 80. Moreover, the first conductors 71 may have a repeated structure (for example, a periodic structure) in at least a partial area as illustrated in the figure and may be a sheet-like conductor that does not have a repeated structure.

The first conductors 71 illustrated in FIG. 35 are the same as the first conductors 71 described in the first embodiment, except that the first conductors 71 are not connected to the connection members 73, may have a repeated structure in a partial area, and may be a sheet-like conductor that does not have a repeated structure. Moreover, the configuration of the dielectric material layer 75 is the same as that of the dielectric material layer 75 described in the first embodiment except that the dielectric material layer 75 does not have an adhesion layer.

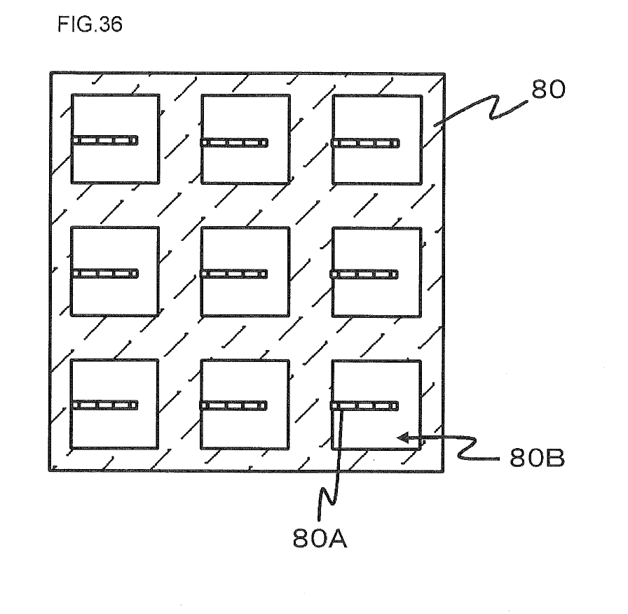

Here, FIG. 36 schematically illustrates an example of a plan-view shape of the third conductor 80. The third conductor 80 includes openings 80B. When the first conductors 71 have a repeated structure that is formed by a plurality of island-shaped conductors 71A, the respective openings 80B are provided at positions where the openings 80B face the plurality of island-shaped conductors 71A arranged repeatedly. Moreover, an interconnect 80A of which one end is electrically connected to the third conductor 80 is formed in the opening 80B.

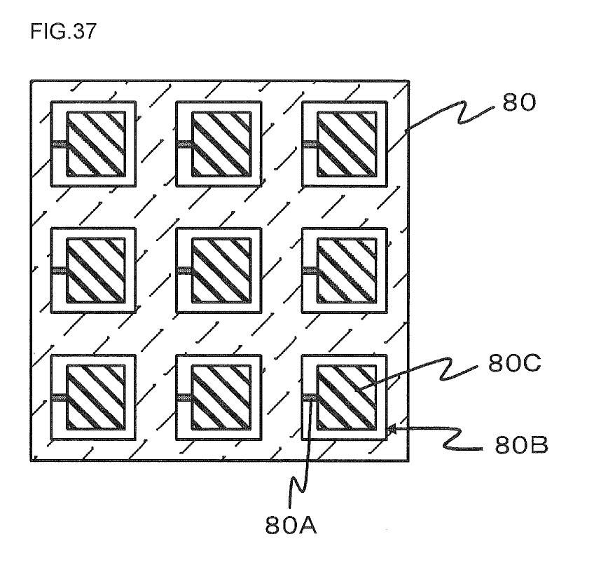

FIG. 37 schematically illustrates another example of a plan-view shape of the third conductor 80. The third conductor 80 includes openings 80B. When the first conductors 71 have a repeated structure that is formed by a plurality of island-shaped conductors 71A, the respective openings 80B are provided at positions where the openings 80B face the plurality of island-shaped conductors 71A arranged repeatedly. Moreover, an interconnect 80A and an opening conductor 80C are formed in the opening 80B. The interconnect 80A electrically connects the third conductor 80 and the opening conductor 80C.

The second dielectric material layer 81 is provided on a surface (a surface on a side opposite to a surface that is in contact with the dielectric material layer 75) of the third conductor 80 and is in contact with the inner wall surface 11. That is, the second dielectric material layer 81 is interposed between the inner wall surface 11 and the third conductor 80. Such a second dielectric material layer 81 maybe an adhesion layer that is formed of natural rubber, an acrylic resin, or silicone. Alternatively, the second dielectric material layer 81 may be a dielectric material layer that is formed on the inner wall surface 11 of the frame 10 using a CVD method, for example. A via 82 is formed in an inner portion of the second dielectric material layer 81.

The via 82 electrically connects the third conductor 80 and the inner wall surface 11. Although the third conductor 80 has a shape such that the third conductor 80 has the opening 80B, and the interconnect 80A (or the interconnect 80A and the opening conductor 80C) is formed in the opening 80C as described above, it is preferable that the via 82 is electrically connected to the third conductor 80 rather than the interconnect 80A and the opening conductor 80C. By doing so, it is possible to realize stable connection.

Here, in the present embodiment, the structure 30 includes an EBG structure. However, the EBG structure included in the structure 30 according to the present embodiment is different from the structure described in the first to ninth embodiments.

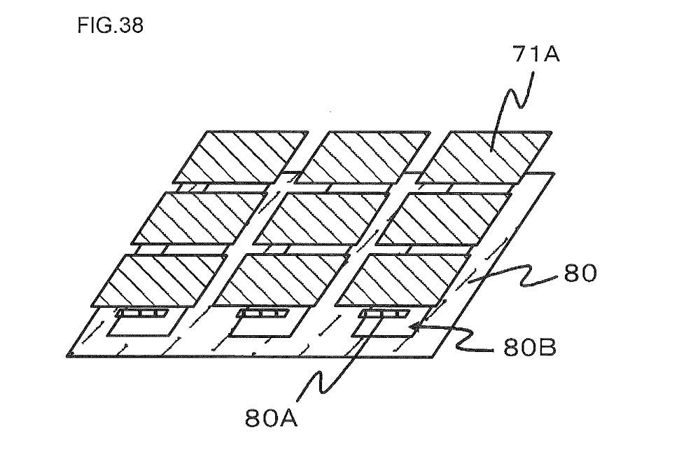

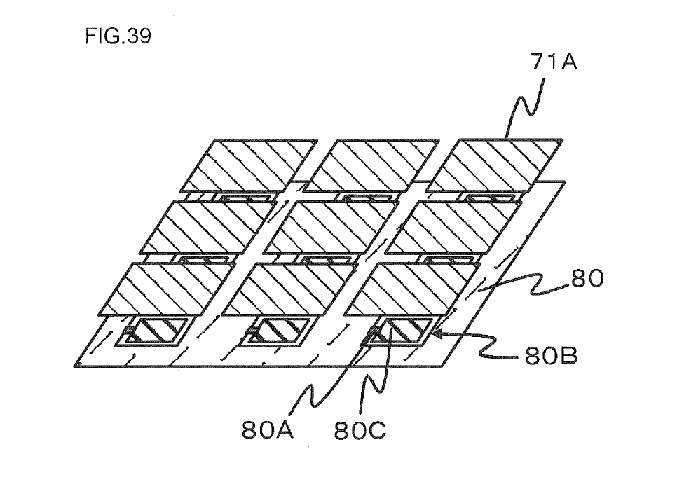

FIGS. 38 and 39 illustrate perspective views schematically illustrating an EBG structure that includes the third conductor 80 and the plurality of island-shaped conductors 71A described above. An equivalent circuit diagram of a unit cell of the EBG structure of FIG. 38 is the equivalent circuit diagram of the unit cell illustrated in FIG. 28, in which the positions of the capacitance C and the inductance L are changed to appropriate positions.

Moreover, an equivalent circuit diagram of a unit cell of an EBG structure in which the island-shaped conductor 1 of the EBG structure of FIG. 38 is substituted with a sheet-like conductor that does not have a repeated structure is the equivalent circuit diagram of the unit cell of the EBG structure of FIG. 38, in which the capacitance C formed between the neighboring island-shaped conductors 1 is removed. Moreover, an equivalent circuit diagram of a unit cell of the EBG structure of FIG. 39 is the equivalent circuit diagram of the unit cell illustrated in FIG. 31, in which the positions of the capacitance C and the inductance L are changed to appropriate positions. Moreover, an equivalent circuit diagram of a unit cell of an EBG structure in which the island-shaped conductor 1 of the EBG structure of FIG. 39 is substituted with a sheet-like conductor that does not have a repeated structure is the equivalent circuit diagram of the unit cell of the EBG structure of FIG. 39, in which the capacitance C formed between the neighboring island-shaped conductors 1 is removed.

A method of manufacturing the electronic apparatus according to the present embodiment can be realized according to the above embodiments. Thus, description thereof will not be provided.

According to the electronic apparatus of the present embodiment, it is possible to suppress propagation of noise current in an area of the inner wall surface 11 where the structure 30 is formed and to suppress propagation of noise electromagnetic waves near the structure 30.

That is, according to the electronic apparatus according to the present embodiment in which the structure 30 is disposed at a predetermined position according to the first embodiment, it is possible to suppress noise current flowing through the inner wall surface 11 of the frame 10 from reaching the gap 40. As a result, it is possible to suppress noise generated due to the operation of the electronic component 20 included in the electronic apparatus from leaking to the outside of the electronic apparatus.

Moreover, in the present embodiment, since it is also possible to adjust the bandgap range of the EBG structure, it is possible to effectively suppress propagation of noise by adjusting the bandgap range of the EBG structure according to the frequency used by the electronic apparatus.

Further, in the present embodiment, the inner wall surface 11 and the structure 30 may form two or more types of EBG structures having different bandgap ranges, and each of the EBG structures maybe disposed repeatedly (for example, periodically). By doing so, it is possible to broaden the bandgap range.

### Examples

Hereinafter, the present invention will be described in detail with reference to Examples.

<Preparation of Sample>

### Comparative Example

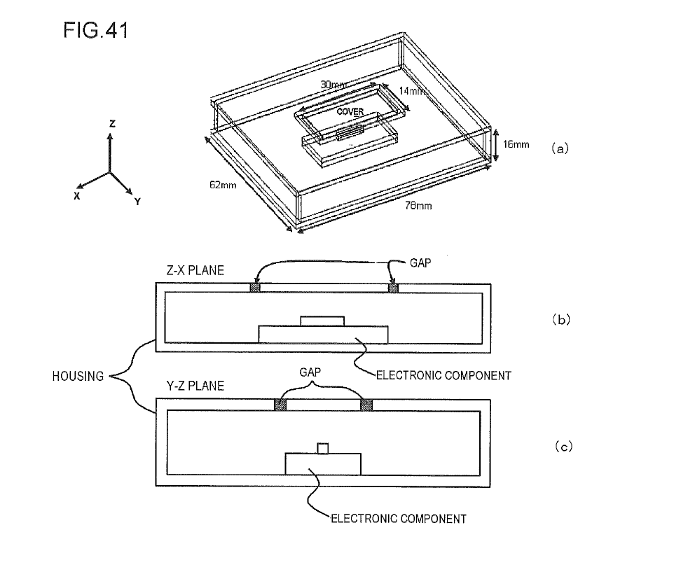

FIG. 41(a) illustrates a perspective view of an electronic apparatus in which an electronic component is formed in an inner portion thereof. FIG. 41(b) illustrates a cross-sectional view of a Z-X plane of the electronic apparatus in which an electronic component is formed in an inner portion thereof. FIG. 41(c) illustrates a cross-sectional view of a Y-Z plane of the electronic apparatus in which an electronic component is formed in an inner portion thereof.

The electronic apparatus of FIG. 41 has a structure in which an electronic component is disposed in a conductive frame having dimensions of 78×62×16 mm. In this frame, an openable cover having a dimension of 14×30 mm is present near approximately at the center of an upper surface thereof, and a small gap is present between the cover and the frame body.

FIG. 41 was used as a comparative example.

### Example

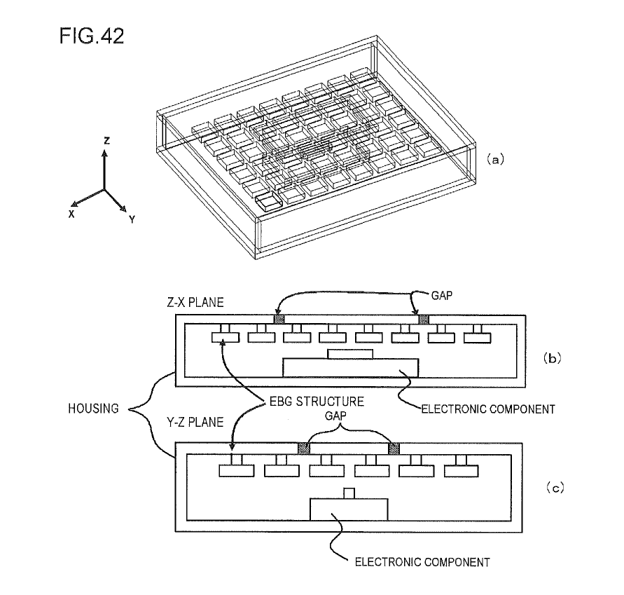

As illustrated in FIG. 42, the same frame as the comparative example was prepared, and the same electronic component as the comparative example was disposed at the same position as the comparative example. Moreover, the structure described in the first embodiment was disposed on the inner wall surface having the gap of the frame so as to surround the gap. The structure was disposed so that when the operating frequency of the electronic component is f (GHz) and the distance in a direction parallel to the inner wall surface from the gap present in the inner wall surface of the frame to the conductive material layer included in the structure that is provided in contact with the inner wall surface is 1 (mm), a relation of 1≦λ/4. Here, λ (mm)=300/f (GHz).

<Electromagnetic Field Simulation>

A signal source, a signal line, and a signal load circuit was provided as the electronic component of FIG. 41, and a magnetic field distribution in and outside a housing at a signal source frequency of 3 GHz was obtained by an electromagnetic field simulation. Further, an admittance and a radiation gain from the signal source were obtained from the simulation results, and electric field intensity was calculated at a distance of 3 m.

Similarly, a signal source, a signal line, and a signal load circuit was provided as the electronic component of FIG. 42, and a magnetic field distribution in and outside a housing at a signal source frequency of 3 GHz was obtained by an electromagnetic field simulation. Further, an admittance and a radiation gain from the signal source were obtained from the simulation results, and electric field intensity was calculated at a distance of 3 m.

<Results>

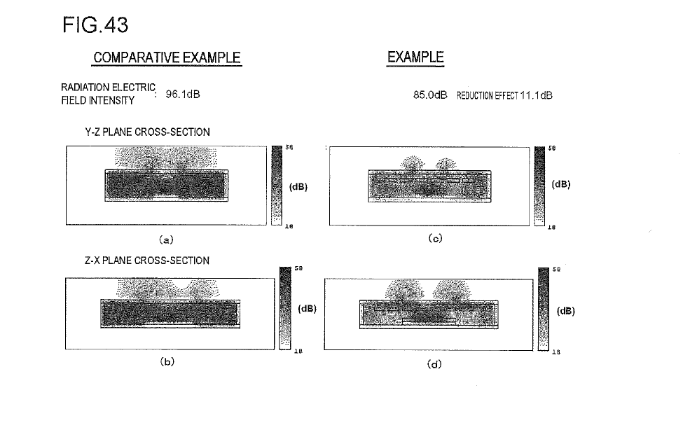

FIG. 43 illustrates electromagnetic field simulation results. FIG. 43(a) illustrates a Y-Z plane cross-sectional magnetic field distribution of the comparative example. FIG. 43(b) illustrates a Z-X plane cross-sectional magnetic field distribution of the comparative example. FIG. 43(c) illustrates a Y-Z plane cross-sectional magnetic field distribution of the present example. FIG. 43(d) illustrates a Z-X plane cross-sectional magnetic field distribution of the present example. The magnetic field intensity is represented in term of a density, and a thicker density represents higher magnetic field intensity. It can be understood that in the case of the present example, the intensity of the magnetic field that radiates from the housing gap to the outside of the housing is decreased as compared to the comparative example. As for the electric field intensity, the present example provides a reduction effect of 11.1 dB as compared to the comparative example.

This application is based upon and claims the benefit of priority from Japanese patent application No. 2010-158205, filed on Jul. 12, 2010, the disclosure of which is incorporated herein in its entirety by reference.

1. An electronic apparatus comprising:
a conductive frame which has conductive properties and has a gap that connects an inner space and an external space;
an electronic component stored in the frame; and
a structure provided in contact with an inner wall surface of the frame, wherein
the structure includes
a conductive material layer, and
a dielectric material layer positioned between the conductive material layer and the inner wall surface of the frame, and
the conductive material layer includes a repeated structure in at least a partial area thereof.

2. The electronic apparatus according to claim 1, wherein
when an operating frequency of the electronic component is f (GHz), and
a length in a direction parallel to the first inner wall surface from the gap present in the first inner wall surface of the frame to the conductive material layer included in the structure that is provided in contact with the first inner wall surface is 1 (mm), a relation of 1≦(300/f)/4 is satisfied.

3. The electronic apparatus according to claim 1, wherein
the structure is provided so as to surround the gap.

4. The electronic apparatus according to claim 1, wherein
the dielectric material layer of the structure includes
a first dielectric material layer that is in contact with the first inner wall surface of the frame,
the conductive material layer of the structure includes a first conductor that is formed in an inner portion of the first dielectric material layer or on a surface on a side opposite to a surface that is in contact with the first inner wall surface so as to face the first inner wall surface, and
the first conductor has the repeated structure in at least a partial area.

5. The electronic apparatus according to claim 4, wherein
the repeated structure of the first conductor comprises a plurality of separated island-shaped conductors, and
the electronic apparatus further includes a connection member that is provided in an inner portion of the first dielectric material layer so as to electrically connect at least a part of the island-shaped conductors and the first inner wall surface.

6. The electronic apparatus according to claim 4, wherein
the repeated structure of the first conductor comprises a plurality of separated island-shaped conductors,
an opening is formed in at least a part of the island-shaped conductors, and
an interconnect of which one end is electrically connected to the island-shaped conductor is formed in the opening.

7. The electronic apparatus according to claim 6, wherein
an opening conductor is formed in the opening, and
the other end of the interconnect is electrically connected to the opening conductor.

8. The electronic apparatus according to claim 4, wherein
the first conductor is formed in an inner portion of the first dielectric material layer, and the repeated structure of the first conductor comprises a plurality of separated island-shaped conductors, and
the electronic apparatus further includes
a first connection member that is formed in an inner portion of the first dielectric material layer so as to be electrically connected to the first inner wall surface and penetrate through the island-shaped conductor in a state where the first connection member is not in contact with the island-shaped conductor, and
a second connection member that is formed on a side opposite to the first inner wall surface with the first conductor interposed so as to be electrically connected to the first connection member.

9. The electronic apparatus according to claim 8, further comprising
a third connection member that electrically connects the second connection member and the island-shaped conductor.

10. The electronic apparatus according to claim 4, wherein
the structure comprises a sheet in which at least a portion of the first dielectric material layer forms an adhesion layer that is attached to the first inner wall surface.

11. The electronic apparatus according to claim 1, wherein
the structure includes
a first dielectric material layer,
a first conductor that is provided in an inner portion of or on a first surface of the first dielectric material layer, has a repeated structure in at least a partial area, and forms the conductive material layer,
a second conductor that is formed on a surface of a side opposite to the first surface of the first dielectric material layer so as to face the first conductor,
a second dielectric material layer that is formed on the second conductor so as to be in contact with the first inner wall surface of the frame, and
a conduction member that is provided in an inner portion of the second dielectric material layer so as to electrically connect the second conductor and the first inner wall surface.

12. The electronic apparatus according to claim 11, wherein
the repeated structure of the first conductor comprises a plurality of separated island-shaped conductors, and
the electronic apparatus further includes a connection member that is provided in an inner portion of the first dielectric material layer so as to electrically connect at least a part of the island-shaped conductors and the second conductor.

13. The electronic apparatus according to claim 11, wherein
the repeated structure of the first conductor comprises a plurality of separated island-shaped conductors,
an opening is formed in at least a part of the island-shaped conductors, and
an interconnect of which one end is electrically connected to the island-shaped conductor is formed in the opening.

14. The electronic apparatus according to claim 13, wherein
an opening conductor is formed in the opening, and
the other end of the interconnect is electrically connected to the opening conductor.

15. The electronic apparatus according to claim 11, wherein
the conduction member comprises a via or a conductive filler.

16. The electronic apparatus according to claim 11, wherein
the structure comprises a sheet in which the second dielectric material layer forms an adhesion layer that is attached to the first inner wall surface.

17. The electronic apparatus according to claim 1, wherein
the electronic apparatus includes an EBG structure that includes one or more types of EBG structures that include the inner wall surface of the frame and the structure that is in contact with the inner wall surface as constituent components thereof.

18. The electronic apparatus according to claim 1, wherein
the structure forms an EBG structure that includes one or more types of EBG structures
